(19) United States
(12) Patent Application Publication
(10) Pub. No.: US 2026/0112572 A1
(43) Pub. Date: Apr. 23, 2026

(54) MULTI-BEAM CHARGED PARTICLE MICROSCOPE FOR INSPECTION WITH IMPROVED IMAGE CONTRAST

(71) Applicant: Carl Zeiss MultiSEM GmbH, Oberkochen (DE)

(72) Inventors: Stefan SCHUBERT, Oberkochen (DE); Andreas ADOLF, Aalen (DE); Dirk ZEIDLER, Oberkochen (DE); Kai SCHUBERT, Oberkochen (DE); Bjoern MIKSCH, Heidenheim (DE); Tobias FELDENGUT, Oberkochen (DE); Maksym KOMPANIIETS, Weissenhorn (DE)

(21) Appl. No.: 19/367,272

(22) Filed: Oct. 23, 2025

Related U.S. Application Data
(63) Continuation of application No. PCT/EP2024/057628, filed on Mar. 21, 2024.

(30) Foreign Application Priority Data
May 2, 2023 (DE) 10 2023 204 008.5

(51) Int. Cl. H01J 37/28; H01J 37/22

(52) U.S. Cl. CPC H01J 37/28; H01J 37/222; H01J 2237/12

(57) ABSTRACT

A multi-beam charged particle system is configured for selecting a first and a second, different image acquisition property, and for acquiring a first image and a second image of a surface of a wafer with a plurality of primary charged particle beamlets. The multi-beam charged particle system is configured for image processing of the first and the second images to obtain at least one processed image. The technology can be used in applications of multi-beam charged particle system, where relatively high beam uniformity and throughput are often desirable. A corresponding method is disclosed. The system and method can yield improved image contrast.

### CROSS-REFERENCE TO RELATED APPLICATIONS

The present application is a continuation of, and claims benefit under 35 USC 120 to, international application No. PCT/EP2024/057628, filed Mar. 21, 2024, which claims benefit under 35 USC 119 of German Application No. 10 2023 204 008.5, filed May 2, 2023. The entire disclosure of each of these applications is incorporated by reference herein.

### FIELD

The disclosure relates to a multi-beam charged particle microscope that can yield improved imaging contrast and a method of operating a multi-beam charged particle microscope for the inspection of semiconductor features with improved image contrast.

### BACKGROUND

WO 2005/024881 A2 discloses an electron microscope system which operates with a multiplicity of electron beamlets for the parallel scanning of an object to be inspected with a bundle of electron beamlets. The bundle of primary charged particle beamlets is generated by directing a primary charged particle beam onto a multi-beam forming unit, comprising at least one multi-aperture plate, which has a multiplicity of openings. One portion of the electrons of the electron beam is incident onto the multi-aperture plate and is absorbed there, and another portion of the beam transmits the openings of the multi-aperture plate and thereby in the beam path downstream of each opening an electron beamlets is formed whose cross section is defined by the cross section of the respective opening. The plurality of primary charged particle beamlets are focused by an objective lens on a surface of a sample and trigger secondary electrons or backscattered electrons to emanate as secondary electron beamlets from the sample, which are collected and imaged onto a detector. Each of the secondary beamlets is incident onto a separate detector element or group of detector elements, so that the secondary electron intensities detected therewith provide information relating to the surface of the sample at the location where the corresponding primary beamlet is incident onto the sample. The bundle of primary beamlets is scanned systematically over the surface of the sample and an electron microscopic image of the sample is generated in the usual way of scanning electron microscopes.

Generally, the imaging contrast of a scanning electron microscope generally depends on the signal generated by secondary electrons, which generally depends on the secondary electron (SE) yield per primary electron and a geometrical collection efficiency of the electron microscope. The SE yield generally depends on material characteristics and the kinetic energy of the primary electrons. The SE yield typically has an angular component, i.e. the SE yield is a typically a function of the polar angle with respect to a surface normal to the sample. In other examples, the SE yield might be influenced by topography effects of the sample surface. Furthermore, the secondary electrons may be generated in a wide range of kinetic energies of the electrons.

Different contrast mechanisms have been proposed to improve an imaging contrast of a multi-beam electron microscope. U.S. Pat. No. 11,049,686 proposes an arrangement of circular of annular aperture filters within a pupil plane of the secondary electron imaging system. The system disclosed in U.S. Pat. No. 11,049,686, however, can be seen as lacking flexibility of most recent inspection tasks of semiconductor structures. In German patent DE 102021124099 B4, a multi-beam electron microscope is disclosed with a detector capable of detecting an angular component of each secondary beamlet. Thereby, an image contrast can be improved by selecting appropriate angular components. The disclosed system offers a relatively large degree of flexibility at the expense of relatively large efforts in a highly complex detection system, involving even more high-speed signal channels. Furthermore, by separating a secondary electron signal in several angular components, the system is more sensitive to noise and might involve larger dwell times or larger primary electron currents.

### SUMMARY

There is a general desire for a less complicated multi-beam electron beam system which offers a high flexibility of different image contrast methods.

The disclosure provides a multi-beam charged particle system and a method of operating a multi-beam charged particle system for image acquisition, which can yield higher contrast. In an example, the effect of a pupil filter with a scanning image acquisition are combined.

Electron microscopy according to the disclosure can comprise an irradiation of a planar surface with a plurality of primary charged particle beamlets. During use, a plurality of secondary electron beamlets is generated at the interaction volumes of the plurality of primary charged particle beamlets with a wafer. The secondary electron yield at each interaction volume depends on the current and kinetic energy of corresponding primary charged particle beamlets and the material composition within the interaction volume. The angular distribution of the secondary electrons generally depends on local charging effects of semiconductor features, including semiconductor features in underlying layers of a wafer, local influences of the extraction field for secondary electrons, or a local topography of the wafer surface in proximity of the interaction volume.

During the irradiation with primary charged particles, the wafer surface typically accumulates local charges. The local charges of the wafer surface can have several different impacts on the secondary electrons. For example, a charging can generate a lateral field gradient at the wafer surface along the scanning direction. The lateral field gradient vector component is oriented parallel to the wafer surface. According to the lateral field gradient, scanning in one direction can generate trailing edges to the secondary electron beamlets. The lateral field gradient can have a large impact on low energy secondary electrons, which travel at a lower speed and thus have a longer time of interaction with the field gradient. For example, a positive charge can be generated, and the low energy secondary electrons can be deflected more than the high energy secondary electrons, which can generate trailing edges in direction opposite to the scanning direction. Thereby, cross talk between imaging channels of the multi beam system can be increased. In an example, a structure on a surface area of a wafer is only weakly charged and has only a minor effect on secondary electrons of high kinetic energy. In an example, a local charging generates an additional field gradient vector component perpendicular to a wafer surface and therefore changes a focus plane of the primary electrons.

According to a first embodiment of the disclosure, a multi-beam charged particle beam system for wafer inspection is provided which can offer a high flexibility of different image contrast methods. The multi-beam charged particle beam system comprises an object irradiation unit with a multi-beamlet generator for generating a plurality of primary charged particle beamlets. The multi-beam charged particle beam system comprises an objective lens for focusing during use the plurality of primary charged particle beamlets into an image plane of the object irradiation unit. The multi-beam charged particle beam system comprises a first common scanning deflector for scanning the plurality or primary charged particle beamlets over an area of the image plane. The multi-beam charged particle beam system further comprises a detection unit configured for imaging a plurality of secondary electron beamlets onto an image sensor. The multi-beam charged particle beam system further comprises a beam splitter unit for guiding the plurality of primary charged particle beamlets from the multi-beamlet generator to the objective lens and for guiding the plurality of secondary electron beamlets from the objective lens to the detection unit. The detection unit comprises a second common scanning deflector for keeping the focus points of the plurality of secondary electron beamlets at a constant position of an image detector. The detection unit further comprises an aperture filter module with at least one selected aperture filter for filtering the secondary electron beamlets. The aperture filter module is arranged in a pupil plane of the detection unit. In an example, the detection unit further comprises a static deflector configured to adjust a position of the plurality of secondary electron beamlets in the pupil plane of the detection unit. In an example, the electron-optical elements of the detection unit are further configured for forming an intermediate image plane of the plurality of secondary electron beamlets, and the static deflector is arranged at the position of the intermediate image plane.

The multi-beam charged particle beam system can further comprise a control unit with a contrast control module. The contrast control module can be configured for controlling during use the first and second common scanning deflectors for scanning image acquisition. The contrast control module can be further configured for controlling the static deflector, and for controlling the aperture filter module. In an example, the aperture filter module comprises a movement mechanism configured for moving, adjusting or exchanging the at least one aperture filter. The contrast control module can be configured for selecting and positioning during use a selected aperture filter with the movement mechanism in a common pupil plane of the detection unit.

The multi-beam charged particle beam system can further comprise a voltage supply unit connected during us to a wafer for providing during use an extraction voltage to the wafer for generating a decelerating field for primary charged particles, corresponding to an accelerating or extraction field for the secondary electrons generated in the interaction volumes. The detection unit can comprise a plurality of adjustable electron-optical elements, configured for forming the pupil plane of the secondary electron beamlets, such that the plurality of secondary beamlets forms a cross over at the pupil plane irrespective of the extraction voltage.

The multi-beam charged particle beam system according to the first embodiment can be configured to generate images of high contrast and low cross-talk by exploiting different effects of the local charges on the primary as well as on the secondary electrons. In a first example, the multi-beam charged particle beam system is configured to control the scanning direction. Thereby, the direction of the lateral field gradient can be changed or adjusted according to a scanning direction. The multi-beam charged particle beam system is configured to repeat a scanning image acquisition with different scanning directions, for example a first scanning image acquisition in a first scanning direction and a second scanning image acquisition opposite to the first scanning direction. Thereby, a first scanning image and a second scanning image are generated which differ in the effect of the lateral field gradient on the secondary electrons.

In a second example, the multi-beam charged particle beam system is configured to control the kinetic energy of the primary electrons. Thereby, the yield of secondary electrons can be adjusted, and a charging of structures under the wafer surface is changed. Thereby, the direction of the lateral field gradient is changed or adjusted, corresponding to a positive or a negative charging of structures under the wafer surface. The multi-beam charged particle beam system is configured to repeat a scanning image acquisition with different kinetic energies, for example a first scanning image acquisition with a first kinetic energy of primary charged particle beamlets, at which a positive charging of the wafer surface is obtained, and a second scanning image acquisition with a second kinetic energy of primary charged particle beamlets, at which a negative charging of the wafer surface is obtained. Thereby, a first scanning image and a second scanning image are generated which differ in the effect of the lateral field gradient on the secondary electrons.

In a third example, the multi-beam charged particle beam system is configured to control the static deflector corresponding to the scanning direction. Thereby, a sensitivity of a filtering of the low-energy secondary electrons with the aperture stop can be improved. In an equivalent alternative, the multi-beam charged particle beam system is configured to control the position of the aperture stop within the pupil plane. Thereby, a sensitivity of a filtering of the low-energy secondary electrons with the aperture stop can be improved. In a fourth example, the multi-beam charged particle beam system is configured to control a repeated scanning image acquisition with different focus positions, for example a first scanning image acquisition with a first focus position and a second scanning image acquisition with a second focus position. Thereby, at least a first and a second scanning image is generated which differ in the effect of the global field gradient vector component perpendicular to the wafer surface. Different focus positions can be achieved by either a fast electrostatic focusing lens integrated in the primary beam path or by a movable wafer holder, which can adjust the position of the wafer surface in direction of the incident primary charge particle beamlets.

According to a second embodiment, a method is provided. The method can improve contrast. The first example according to the second embodiment relies on the acquisition of a first image in a first scanning direction and at least a second image in a second scanning direction, which is opposite to the first scanning direction. For example, a difference image computed from the first and the second image corresponds to crosstalk according to the trailing edges generated by lateral field gradients.

The charging contrast can be increased by special placement of the beam aperture stop at secondary electron beam path. Low energy secondary electrons are usually emitted at a smaller angular cone and therefore typically at the center of the angular distribution of the secondary electrons in the pupil or aperture stop plane. By decentering the aperture stop, a deflection of the low energy secondary electrons due to the lateral field gradient described above can be more pronounced and has a greater impact on the imaging contrast. According to a second example of the second embodiment, a method of contrast improvement is provided, comprising a step of decentering the aperture filter in direction parallel to the scanning direction. Thereby, higher sensitivity of the filtering to low energy secondary electrons is achieved. In an example, the method comprises the steps of selecting a selected aperture filter and positioning the selected aperture filter with a movement mechanism in the common pupil plane of the detection unit. A movement mechanism can comprise a linear or rotary slider. Thereby, a charging contrast of weak charging objects is increased and a weak charging of structures under the wafer surface becomes visible.

According to a third example of the second embodiment, a method of contrast improvement is provided. The second method relies on the acquisition of a first image with a first kinetic energy of primary charged particles and at least a second image with a second kinetic energy of primary charged particles with a different charging property compared to the first image. The difference image computed from the first and the second image corresponds to crosstalk according to the trailing edges generated by different lateral field gradients.

According to a fourth example of the second embodiment, a method of contrast improvement is provided. The third method relies on the acquisition of a first image with a first position of the image surface with respect to the wafer surface and at least a second image with a second, different position of the image surface with respect to the wafer surface. The position of the image surface with respect to the wafer surface is adjusted either by adjusting a fast electrostatic focusing lens within the primary beam-path or by adjusting the axial position of the wafer sample holder. From the first and the at least second image, a high-resolution image is computed, were the different parts the first and second image, which are not in perfect focus position of the primary charged particle beamlets with respect to the wafer surface, is removed. Thereby, a local focus blur according to a local charging effect is reduced. Thereby, also any effects of a field curvature and image plane tilt is reduced. In an example, a high-resolution image is obtained from a focus stack of images comprising the first and at least second image. Thereby, from a perfectly flat wafer surface at least two multi-beam images are acquired with a change of the focal plane or working distance. In an example, a stack of images through focus or working distance is acquired from the perfectly flat sample surface, and a 2D image of highest resolution is computed by image processing methods selected from a group of methods including image stitching, local deconvolution, or phase retrieval. By this way, charging effects or any other deviations of the focus positions of the plurality of primary charged particle beamlets from a perfectly flat wafer surface are compensated and an image of ultimate resolution is computed. Other deviations can be for example a result of a field curvature or image plane tilt, which is common in multi-beam charged particle beam systems.

Charging effects are usually subject to a decay of residual charges at a substrate surface. Discharging in semiconductors is typically induced by thermal diffusion or leakage. Thus, surface charges can change over time. In a further example, a method is provided, comprising acquiring a first image of a first surface segment at a first position on a wafer surface and subsequently acquiring a second image of a second surface segment at a second position on a wafer surface. The method can improve contrast. In an example, the first and second positions are selected such that the first and second surface segment form a gap in between. The method can comprise an acquisition of the third image of a third surface segment at a third position on a wafer surface, whereby the third surface segment is adjacent to the first surface segment. Thereby, a time interval between imaging of the first and the adjacent third surface segment can be increased and any charging at the first surface segment is reduced by the increased time interval for discharging effects to happen.

In an example, the image area is divided in smaller subfields, with a smaller subfield for each of the plurality of primary charged particle beamlets, such that with a single scan only a partial image of a surface area is acquired. Several parallel scans of smaller subfields are acquired to collect several partial images, which are stitched together. Thereby a charging effect is reduced.

In an example, a series of at least two images is obtained, wherein the image area is shifted by the size of one subfield between the first and second images. Thereby, charging effects in a periphery of an image area is reduced and a beam-to-beam variation is reduced.

The embodiments and examples can be combined. It is also possible to combine more than two methods or examples. For example, a second or third image can be obtained by scanning in a different scanning direction and obtained at a different focus position or different working distance.

According to the second embodiment, a method is provided. The method can improve contrast for a wafer inspection task. The method can comprise the step of illuminating a surface of a wafer with a plurality of primary charged particle beamlets of a multi-beam charged particle beam system. Thereby, a plurality of secondary electron beamlets can be excited from a plurality of interaction volumes generated by the plurality of primary charged particle beamlets with the wafer. The method can comprise the step of collecting the plurality of secondary electron beamlets with an objective lens and the step of collecting the signals of each of the plurality of secondary electron beamlets with an image sensor for generating an image of a surface of a wafer with enhanced contrast of a semiconductor feature of interest.

A method according to the second embodiment can further comprise the steps of positioning an inspection position of a surface of a wafer and determining a selected contrast mechanism at the inspection position and executing the selected contrast mechanism. The inspection position of a surface of a wafer is typically arranged with a wafer stage comprising six axis control and for example an interferometer for precision control of position and alignment. With the selected contrast mechanism, a digital image of semiconductor features of the wafer can be determined at the inspection position by image processing. In an example, the method further comprises a step of evaluating a first image contrast of the digital image and a step of modifying the selected contrast mechanism by modifying at least one of the contrast mechanisms according to any example of the second embodiment or any combination thereof. An image acquisition of the surface of a wafer is repeated with the modified contrast mechanism and an improved contrast mechanism can be determined with improved image contrast compared to the first image contrast. In an example, the modified or improved contrast mechanism is stored in a memory for use with the inspection position. With the method, a contrast mechanism can be optimized for improved imaging contrast at each inspection position. A further inspection task at a comparable inspection position at for example another wafer or another die can thus be performed with a pre-determined contrast mechanism.

In an example, the method further comprises the step of performing an image evaluation of the digital image of semiconductor features of the wafer to determine a defect. A defect is generally described by at least one of an excess deviation of a size, an area, a material composition of a semiconductor feature, or an excess feature, for example a contamination particle. In an example, the method further comprises the step of repeating the image acquisition of the surface of a wafer at plural inspection positions, for example including a first and a second, different contrast mechanism, and a step of evaluating a distribution of defects to determine at least one of random defects, regular defects, or clusters of defects.

By the embodiments or examples of the disclosure, a multi-beam charged particle beam system and a method of operating a multi-beam charged particle beam system with improved image contrast is provided. The disclosure allows therefore a wafer inspection with higher precision and with a higher accuracy. It will be understood that the disclosure is not limited to the embodiments and examples but comprises also combinations and variations of the embodiments and examples.

### BRIEF DESCRIPTION OF THE DRAWINGS

Embodiments of the present disclosure will be explained in more detail with reference to drawings, in which:

FIG. 1 is a schematic sectional view of a multi-beam charged particle system according to the first embodiment;

FIGS. 2a-c illustrate an example of a scanning image acquisition of a surface segment of a wafer;

FIG. 3 illustrates an example of an ideal imaging condition;

FIGS. 4a-b illustrate an example of an imaging in the presence of a charging effect;

FIGS. 5a-c illustrate different charging effects in the pupil plane of the detection unit;

FIG. 6 illustrates a secondary electron yield over primary electron energy;

FIG. 7 illustrates an example of a detection unit;

FIGS. 8a-b illustrate an example of ghost image formation with a multi-beam imaging system;

FIGS. 9a-c illustrate an effect of a charging of a sample surface and a result of an image processing;

FIGS. 10a-c illustrate a pupil distribution of secondary electrons in the presence of charging effects;

FIGS. 11a-b illustrate the different charging due to different kinetic energies or landing energies of primary electrons;

FIG. 12 illustrates an example of detecting a leakage defect using a method according to the disclosure;

FIGS. 13a-c illustrate a filtered image generation without charging;

FIGS. 14a-c illustrate a filtered image generation with a weak charging effect;

FIG. 15 illustrates the dependency of a filtered image generation from the scanning direction;

FIGS. 16a-c illustrate an example of an improved image acquisition of features with moderate charging effects;

FIGS. 17a-c illustrate an example of an image processing images of moderate charging features;

FIG. 18a illustrates a curvature of an image surface and a stack of image surfaces;

FIG. 18b illustrates an image processing out of at least two images;

FIG. 19 illustrates a method according to the second embodiment;

FIG. 20 illustrates an example according to an image acquisition method;

FIGS. 21a-b illustrate a further example according to an image acquisition method; and

FIGS. 22a-c illustrate a further example according to an image acquisition method.

### DETAILED DESCRIPTION

In the exemplary embodiments of the disclosure described below, components similar in function and structure are indicated as far as possible by similar or identical reference numerals.

Some array elements, for example the plurality of primary charged particle beamlets, are identified by a reference number. Depending on the context, the same reference number may also identify a single element out or the array elements. Each primary charged particle beamlet (3.1, 3.2, 3.3) is one of the plurality of primary charged particle beamlets (3).

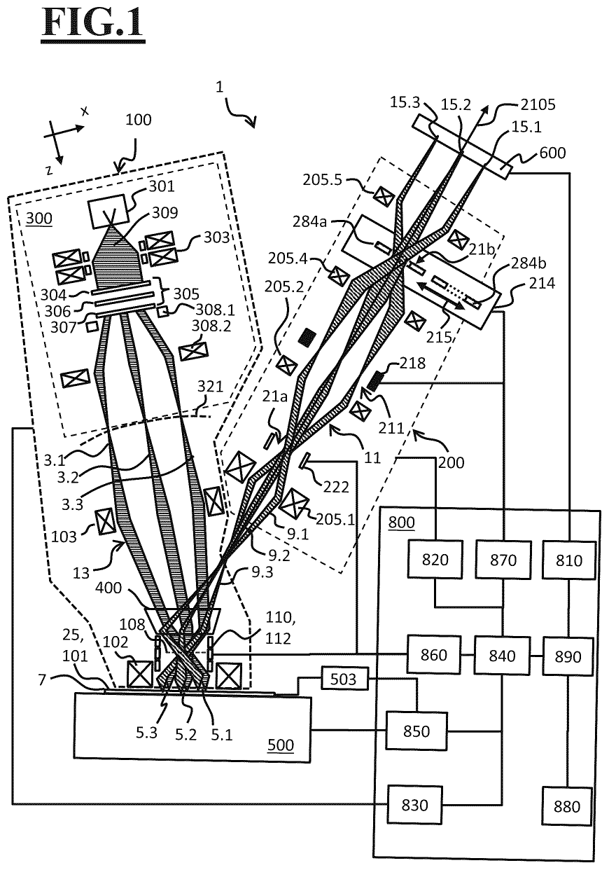

The schematic representation of FIG. 1 illustrates basic features and functions of a multi-beam charged-particle system 1 according to a first embodiment. It is to be noted that the symbols used in the figure have been chosen to symbolize their respective functionality. The type of system shown is that of a multi-beam scanning electron microscope using a plurality of primary charged particle beamlets 3 for generating a plurality of primary charged particle beam spots 5 on a surface 25 of an object 7, such as a structured wafer or mask substrate located with a top surface 25 in an image surface 101 of an objective lens 102. For simplicity, only three primary charged particle beamlets 3.1 to 3.3 with three primary charged particle beam spots 5.1 to 5.3 are shown. The features and functions of multi-beamlet charged-particle system 1 can be implemented using electrons or other types of primary charged particles such as ions, such as Helium ions. Further details of the microscope system 1 are provided in International Patent application PCT/EP2021/066255, filed on Jun. 16, 2021, which is hereby fully incorporated by reference.

The system 1 comprises an object irradiation unit 100 and a detection unit 200 and a secondary electron beam divider or beam splitter unit 400 for separating the secondary charged-particle beam path 11 from the primary charged-particle beam path 13. The object irradiation unit 100 comprises a charged-particle multi-beam generator 300 for generating the plurality of primary charged-particle beamlets 3 and is adapted to focus the plurality of primary charged-particle beamlets 3 into the image surface 101, in which the surface 25 of an object or wafer 7 is positioned by a sample stage 500.

The primary beam generator 300 produces a plurality of primary charged particle beamlet spots in an intermediate image surface 321. The primary beamlet generator 300 comprises at least one source 301 of primary charged particles, for example electrons. The at least one primary charged particle source 301 emits a diverging primary charged particle beam, which is collimated by at least one collimating lens 303 to form a collimated or parallel primary charged particle beam 309. The collimating lens 303 is usually consisting of one or more electrostatic or magnetic lenses, or by a combination of electrostatic and magnetic lenses. The collimated primary charged particle beam 309 is incident on the primary multi-beam forming unit 305. A multi-beam generating unit 305 is for example explained in US 2019/0259575, and in U.S. Pat. No. 10,741,355 B1, both hereby incorporated by reference. The multi-beam forming unit 305 basically comprises a first multi-aperture plate or filter plate 304 illuminated by the collimated primary charged particle beam 309. The first multi-aperture plate or filter plate 304 comprises a plurality of apertures in a raster configuration for generation of the plurality of primary charged particle beamlets 3, which are generated by transmission of the collimated primary charged particle beam 309 through the plurality of apertures. The multi-beamlet forming unit 305 comprises at least one further multi-aperture plate 306, which is located, with respect to the direction of movement of the electrons in beam 309, downstream of the first multi-aperture or filter plate 304. For example, a second multi-aperture plate 306 comprises for example four or eight of electrostatic elements for each of the plurality of apertures, for example to deflect each of the plurality of beamlets individually. The multi-beamlet forming unit 305 according to some embodiments is configured with a terminating multi-aperture plate 307. The multi-beamlet forming unit 305 is further configured with an adjacent electrostatic field lenses 308.1, which is in some examples combined in the multi-beamlet forming unit 305. Together with a second field lens 308.2, the plurality of primary charged particle beamlets 3 is focused in or in proximity of the intermediate image surface 321. The primary charged-particle source 301 and each of the active multi-aperture plates 306 are controlled by primary beam-path control module 830.

The plurality of focus points of primary charged particle beamlets 3 passing the intermediate image surface 321 is imaged by field lens group 103 and objective lens 102 into the image surface 101, in which the surface 25 of the object 7 is positioned. A decelerating electrostatic field is generated between the objective lens 102 and the object surface 25 by application of a voltage to the object by the sample voltage supply 503. With the decelerating electrostatic field generated by sample voltage supply 503, a kinetic landing energy of primary electrons is adjusted to for example below 2 keV, below 1 keV, below 500 eV, below 300 eV or even less.

The object irradiation system 100 further comprises a collective multi-beam raster scanner 110 in proximity of a beam cross over 108 by which the plurality of charged particle beamlets 3 can be deflected in a direction perpendicular to the propagation direction of the charged particle beamlets 3. The propagation direction of the primary beamlets throughout the examples is in positive z-direction. Objective lens 102 and collective multi-beam raster scanner 110 are centered at an optical axis (not shown) of the multi-beam charged-particle system 1, which is perpendicular to wafer surface 25. The plurality of primary charged particle beamlets 3, forming the plurality of beam spots 5 arranged in a raster configuration, is scanned synchronously over the surface 25. In an example, the raster configuration of the focus spots 5 of the plurality of J primary charged particle 3 is a hexagonal raster of about one hundred or more primary charged particle beamlets 3, for example J=91, J=100, or J approximately 300 or more beamlets. The primary beam spots 5 have a distance about 6 μm to 45 μm between each other, and a diameter of below 5 nm, for example 3 nm, 2 nm or even below. In an example, the beam spot size is about 2 nm, and the distance between two adjacent beam spots is 8 μm. At each scan position of each of the plurality of primary beam spots 5, a plurality of secondary electrons is generated, respectively, forming the plurality of secondary electron beamlets 9 in the same raster configuration as the primary beam spots 5. The intensity of secondary charged particle beamlets 9 generated at each beam spot 5 depends on the intensity of the impinging primary charged particle beamlet 3, illuminating the corresponding spot 5, the material composition and topography of the wafer 7 under the beam spot 5, and the charging condition of the wafer 7 at the beam spot 5. The plurality of secondary charged particle beamlets 9 are accelerated by the same electrostatic field between objective lens 102 and object surface 25, generated by voltage supply 503, and are collected by objective lens 102 and pass the first collective multi-beam raster scanner 110 in opposite direction to the primary beamlets 3. The plurality of secondary beamlets 9 is scanning deflected by the first collective multi-beam raster scanner 110. The plurality of secondary charged particle beamlets 9 is then guided by secondary electron beam divider or beam splitter unit 400 to follow the secondary beam path 11 to the detection unit 200. The plurality of secondary electron beamlets 9 is travelling in opposite direction from the primary charged particle beamlets 3, and the beam splitter unit 400 is configured to separate the secondary beam path 11 from the primary beam path 13 usually using magnetic fields or a combination of magnetic and electrostatic fields.

Detection unit 200 images the secondary electron beamlets 9 onto the image sensor 600 to form there a plurality of secondary charged particle image spots 15. The detector or image sensor 600 comprises a plurality of detector pixels or individual detectors. For each of the plurality of secondary charged particle beam spots 15, the intensity is detected separately, and the property of the object surface 25 is detected with high resolution for a large image patch of the object 7 with high throughput. For example, with a raster of 10×10 beamlets with 8 μm pitch, an image patch with a diameter D of approximately 88 μm×88 μm is generated with one image scan with collective multi-beam raster scanner 110, with an image resolution of for example 2 nm or below. The image patch is sampled with half of the beam spot size, thus with a pixel number of 8000 pixels per image line for each beamlet, such that the image patch generated by 100 beamlets comprises 6.4 gigapixel. The digital image data is collected by imaging control module 810. Details of the digital image data collection and processing, using for example parallel processing, are described in international patent application WO 2020151904 A2 and in U.S. Pat. No. 9,536,702, which are hereby incorporated by reference.

Detection unit 200 further comprises at least a second collective raster scanner 222, which is connected to scanning and imaging control unit 860. Scanning control unit 860 is configured to compensate a residual difference in position of the plurality of focus points 15 of the plurality of secondary electron beamlets 9, such that the positions of the plurality secondary electron focus spots 15 are kept constant at image sensor 600.

The detection unit 200 comprises further electrostatic or magnetic lenses 205.1 to 205.5 and a second cross over or pupil plane 21b of the plurality of secondary electron beamlets 9, in which a contrast aperture filter module 214 is located. The second cross over corresponds to a pupil plane 21b of the detection unit 200. In a pupil plane, a lateral coordinate with respect to the optical axis 2105 corresponds to a propagation angle of a secondary electron trajectory at the image surface 101. The propagation angle of a secondary electron trajectory is measured relative to the wafer surface normal, which is corresponding to the optical axis 2105 of the detection unit 200. The detection unit 200 further comprises a static deflector 218 for commonly deflecting the plurality of secondary electron beamlets 9. The static deflector 218 is arranged in proximity to an intermediate image plane 211, such that the position of the focus spots 15 on the detector is not influenced by the static deflector 218. Instead, with deflector 218, a position of the secondary electron beamlets at pupil plane 21b can be adjusted.

The image sensor 600 is configured by an array of sensing areas in a pattern compatible to the raster arrangement of the secondary electron beamlets 9 focused by the projecting lenses 205 onto the image sensor 600. This enables a detection of each individual secondary electron beamlet independent from the other secondary electron beamlets incident on the image sensor 600. The image sensor 600 illustrated in FIG. 1 can be an electron sensitive detector array such as a CMOS or a CCD sensor. Such an electron sensitive detector array can comprise an electron to photon conversion unit, such as a scintillator element or an array of scintillator elements. In another embodiment, the image sensor 600 can be configured as electron to photon conversion unit or scintillator plate arranged in the focal plane of the plurality of secondary electron particle image spots 15. In such an embodiment, the image sensor 600 can further comprise a relay optical system for imaging and guiding the photons generated by the electron to photon conversion unit at the secondary charged particle image spots 15 on dedicated photon detection elements, such as a plurality of photomultipliers or avalanche photodiodes (not shown). Such an image sensor is disclosed in U.S. Pat. No. 9,536,702, which is hereby incorporated by reference.

During an acquisition of an image patch by scanning the plurality of primary charged particle beamlets 3, the stage 500 is optionally not moved, and after the acquisition of an image patch, the stage 500 is moved to the next image patch to be acquired. In an alternative implementation, the stage 500 is continuously moved in a second direction while an image is acquired by scanning of the plurality of primary charged particle beamlets 3 with the collective multi-beam raster scanner 110 in a first direction. Stage movement and stage position is monitored and controlled by sensors known in the art, such as Laser interferometers, grating interferometers, confocal micro lens arrays, or similar.

During an image scan, the control unit 800 is configured to trigger the image sensor 600 to detect in predetermined time intervals a plurality of timely resolved intensity signals from the plurality of secondary electron beamlets 9, and the digital image of an image patch is accumulated and stitched together from all scan positions of the plurality of primary charged particle beamlets 3.

The control unit 800 of the multi-beamlet charged-particle system 1 further comprises an-imaging control module 810, configured to receive the data streams from the image sensor 600 and to generate a digital image of the surface of the sample 7 during operation; a secondary beam-path control module 820, configured to control the lenses 205 and other components of the detection unit 200; a primary beam-path control module 830, configured to control the elements of the object irradiation unit 100, including the charged-particle multi-beamlet generator 300; a stage control module 850, configured to control the stage positioning and alignment, and including control of the sample voltage supply unit 503; a scanning operation control module 860, configured to control a scanning operation by the first collective multi-beam raster scanner 110 and the second scanning deflection system 222; a control operation processor unit 840, configured to execute inspection tasks of samples, and configured to control the modules 810, 820, 830, 850, 860, 870 and a memory 880 for storing software instructions and image data. The control operation processor unit 840 is further connected to an interface (not shown) for exchange of data, instructions, software, or user interaction. A control unit 800 according to the first embodiment further comprises an image processing engine 890, which is configured to perform image processing operations of at least one digital image.

The control unit 800 of the multi-beamlet charged-particle system 1 according to the disclosure further comprises a contrast control module 870, connected to the control operation processor unit 840. The contrast control module 870 is configured to receive instruction from the control operation processor unit 840 to control an image acquisition property of the imaging of a surface segment of the wafer 7. The contrast control module 870 is connected to an aperture filter module 214 and configured to select an aperture filter 284 according to the image acquisition property. For simplicity, only two different aperture filters 284a and 284b are shown, but there can be provided more than two different aperture filters 284. The aperture filters 284 can be mounted on an alignment and exchange mechanism, such as a rotary or linear moving mechanism 215 for placement and alignment of a selected aperture filter 284a at the pupil position 21b of the plurality of secondary electron beamlets 9.

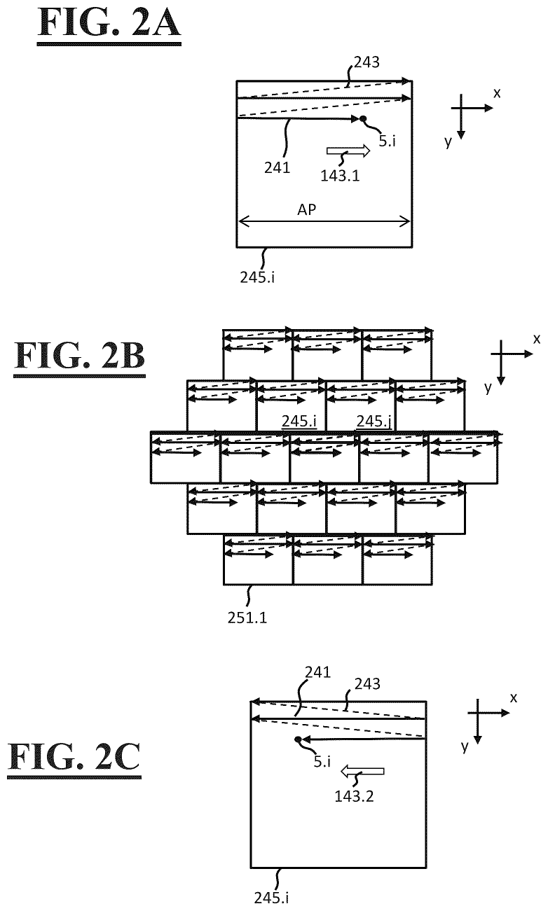

FIGS. 2a-c illustrate a scanning operation of the plurality of primary charged particle beamlets 3 during an image acquisition. The scanning operation control module 860 is configured to provide during use a scanning signal to scanning deflector 110. Thereby, each primary charged particle beamlet 3 is deflected by the collective multi-beam raster scanner 110 such that the corresponding focus spot 5.i is scanned over an image patch 245.i of a single beamlet (FIG. 2a). Each image patch 245.i has a diameter AP of for example 8 μm to 10 μm. The scanning operation comprises a scanning of a plurality of parallel image scanning lines 241 along scanning direction 143.1 for image acquisition. At the end of each image scanning line 241, each beamlet 3 is moved back to the starting position of a next scanning line, which is also called “flyback” 243. During image acquisition along image scanning lines 241, the scanning operation is controlled to achieve a dwell time of about 50 ns at each image point, with for example 8000 images points per image scanning line 241. The time for flyback 243 can be much shorter, for example 20 ns in total. FIG. 2b shows the parallel operation of a plurality of primary charged particle beamlets 3 to acquire an image 251.1 of a surface segment or surface area 251.1 of a wafer surface, consisting of a plurality of image patches 245. According to an example, the scanning operation control module 860 is configured to change the first scanning direction 143.1 into a second scanning direction 143.2 (FIG. 2c). In the example, the second scanning direction 143.2 is opposite to the first scanning direction 143.1, but other scanning directions, for example a second scanning direction inclined by an angle, are possible as well.

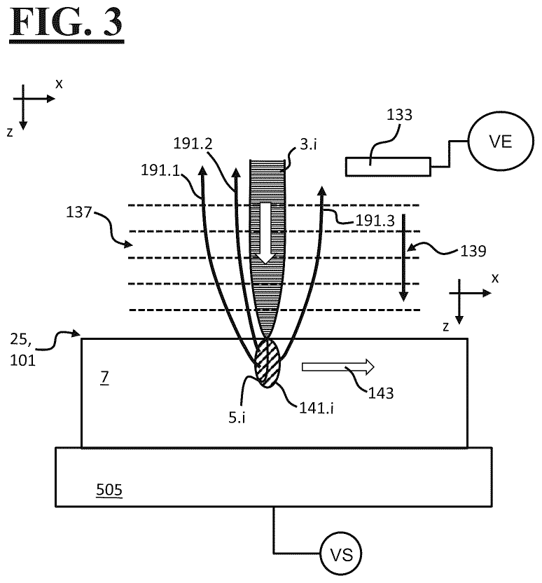

FIG. 3 illustrates an ideal imaging operation at on image point. A primary charged particle 3.i is focused such that a focus spot 5.i in an image surface 101. In ideal circumstances, the image surface 101 is a perfectly flat plane, into which the surface 25 of a planar wafer or mask 7 is arranged by stage control module 850. The position of the image surface 101 in z-direction is adjusted by primary beam-path control module 830. Further, the landing energy of the primary electrons is adjusted by sample voltage supply 503. Sample voltage supply 503 provides a voltage VS to the sample 7, and a further voltage VE is provided to electrode 133 the object irradiation unit (100). Thereby, a parallel extraction field 137 (illustrated by equipotential lines) is generated during use, with electrical field vectors 139 being perpendicular to the wafer surface 25. The primary electrons generate an interaction volume 141.i below the surface 25 of the wafer or mask 7, in which secondary electrons are generated. Secondary electrons of negative charge are extracted and accelerated by electrical field 139 along secondary electron trajectories 191. Three examples of secondary electron trajectories 191.1 to 191.3 are shown. After collecting sufficient secondary electrons during the dwell time of about 50 ns, the primary beamlet 3.i is moved by scanning deflector (not shown) along scanning direction 143 to the next image pixel position.

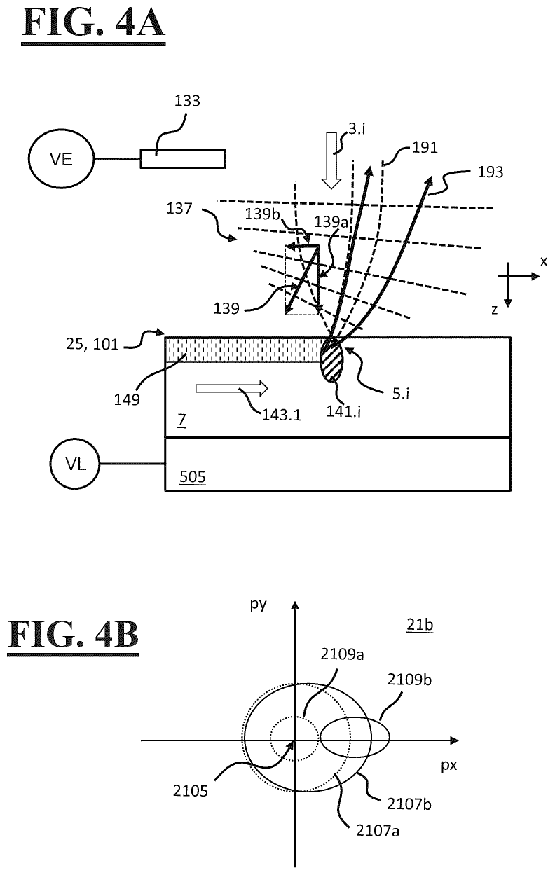

FIG. 4a illustrates a typical charging effect during imaging. Same reference number as in FIG. 3 are used and reference is also made to FIG. 3. From previous scanning positions along scanning direction 143.1, a pre-exposed surface area 149 is generated. The pre-exposed surface area 149 has collected a residual charge, which generates an additional electrical field. Thereby, the extraction field 137 is deteriorated at the edge of the pre-exposed surface area 149, and secondary electrons experience an extraction field vector 139, which is not perpendicular to the wafer surface 25 anymore. In this example, a negative charge is built up in the pre-exposed surface area 149, and the extraction field vector 139 generates an accelerating force with an additional vector component 139b in scanning direction. The secondary electrons are accelerated to follow secondary electron trajectories 193 with an additional angular component in scanning direction.

An effect of the additional vector component 139b in scanning direction is illustrated in FIG. 4b. FIG. 4b shows the pupil distribution of the secondary electron beamlets 9 in the pupil plane 21b with pupil coordinates px, py, centered at the optical axis 2105 of the detection unit 200. The pupil distribution 2107a and 2109a illustrates the ideal case of a non-charging object. In presence of charging effects, the pupil distribution 2107a receives an angular component according to the additional vector component 139b and is deformed in scanning direction (here parallel to x-direction) into pupil distribution 2107b. The effect is more pronounced for the low-energy secondary electrons, which are more deflected in scanning direction from ideal pupil distribution 2109a into distribution 2109b.

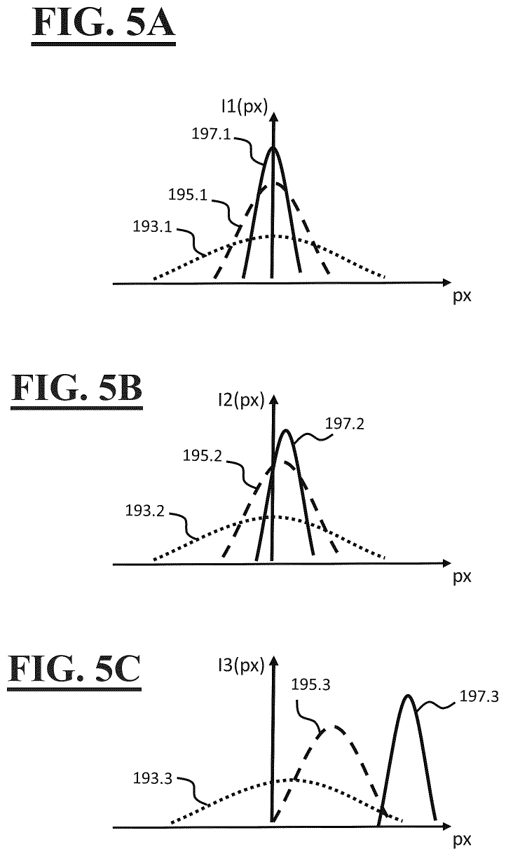

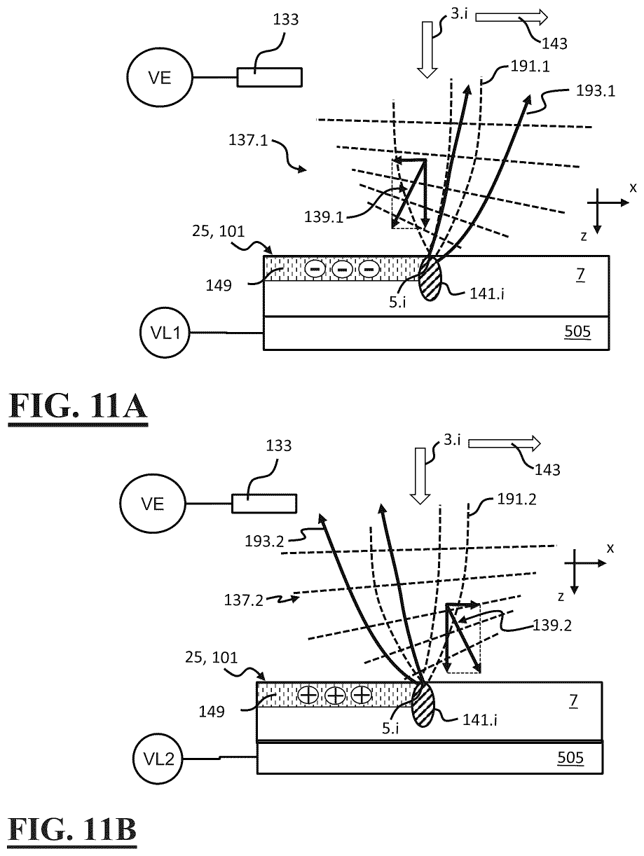

The pupil distribution or angular spectrum of the secondary electrons is further illustrated in FIGS. 5a-c. Typically, secondary electrons are generated in the interaction volumes 141 (see FIG. 4a) and leave the sample with kinetic energies between for example 0.1 eV and 10 eV. The secondary electrons are then accelerated by extraction field 139. FIG. 11a illustrates the angular spectrum distribution of secondary electrons without any charging effects. FIG. 11a shows the angular distribution of secondary electrons of high kinetic energy 193.1 with for example energies above 5 eV. Secondary electrons of higher kinetic energy are extracted and accelerated from a larger angular spectrum distribution and thus form an angular distribution with larger extension. FIG. 11a further shows the angular distribution of secondary electrons of medium kinetic energy 195.1 (e.g. with energies between 2 eV and 5 eV), and the angular distribution of secondary electrons of low kinetic energy 197.1 (e.g. with energies below 2 eV). The angular distribution of secondary electrons of low kinetic energy 197.1 shows the smallest angular extension or width. All angular distributions of secondary electrons are centered at the pupil plane. FIG. 11b illustrates the situation of a low or weak charging effect. Due to a weak charging effect, only small lateral field components 139b are generated, which predominantly influence the secondary electrons of low kinetic energy with angular distribution 197.2. The other two spectra 193.2 and 195.2 do not show a significant influence. FIG. 5c illustrates a strong charging effect. Here, secondary electrons of all energy regimes 193.3, 195.3 and 197.3 are deflected, however, the low-energy secondary electrons 197.3 again show the largest effect.

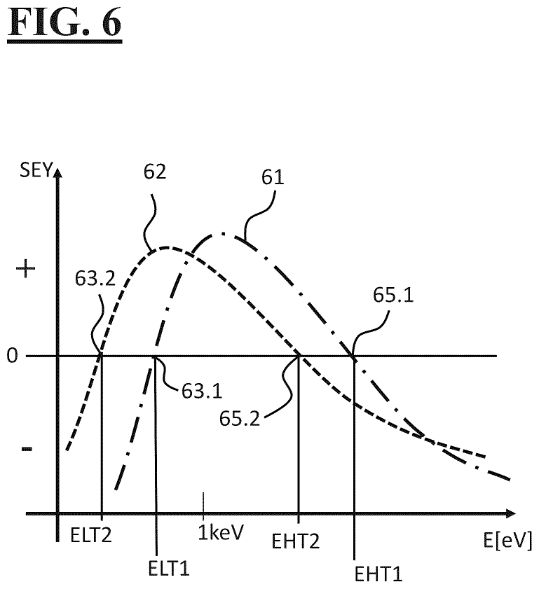

FIG. 6 illustrates a charging effect in isolating material. The secondary electron yield SEY versus the incident primary electron count is shown as a function of primary electron energy E for two different semiconductor materials in curves 61 and 62. Both curves show primary electron energy spectra which create a positive or a negative charge within the semiconductor materials. At two transition energies, the SEY is in balance, meaning that the number of incident primary electrons and extracted secondary electrons is balance such that no surface charging occurs. However, the low energy transition points 63.1 at ELT1 and 63.2 at ELT2 as well as the high energy transition points 65.1 at EHT1 and 65.2 at EHT2 are not at the same kinetic energy of the primary electrons, for example ELT1 is unequal to ELT2. Thus, the charge accumulated during scanning image acquisition in a pre-exposed surface area 149 is typically either positive or negative, and the low energy secondary electrons are either deflected in scanning direction 143 or opposite to scanning direction 143.

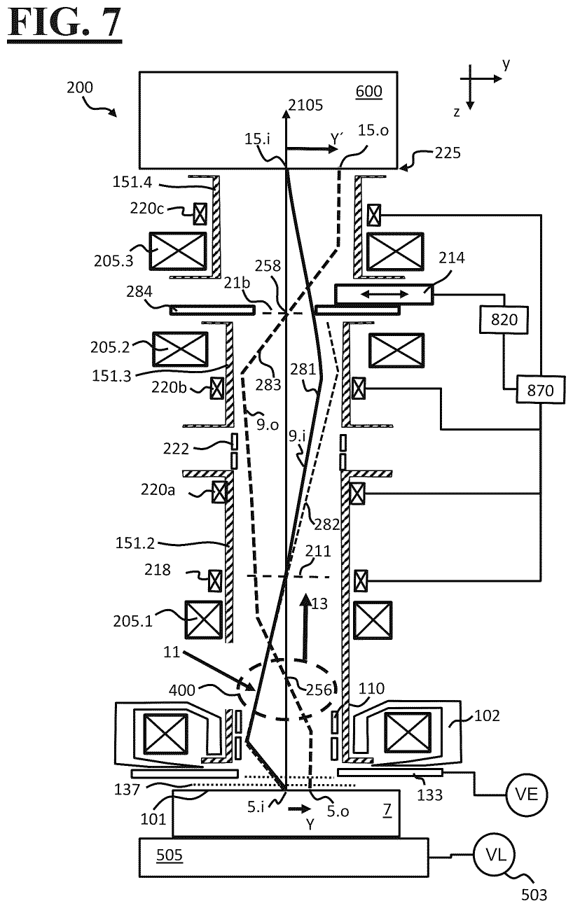

FIG. 7 illustrates the detection unit 200 and further components already shown in FIG. 1, which are labelled by same reference numbers and reference is made to the description of FIG. 1. The primary charged particle beamlets are schematically shown by primary beam path 11. The FIG. 6 illustrates the secondary electron beam path at the example of two selected electron trajectories 281 and 283 of two secondary electron beamlets 9.i and 9.o. There are more secondary electron beamlets, corresponding to the plurality of primary charged particle beamlets, which are focused onto the surface 25 of a sample 7 (with only to focus points 5.o and 5.i shown). The detection unit 200 comprises a second branch 151.2 of the common beam tube 151 and further beam tube segments 151.2 and 151.4, which are connected to a voltage supply and set to tube voltage VT. VT can for example be ground potential. Through the tube 151, primary charged particles propagate with constant high kinetic energy of for example E1=30 keV. Through the tube 151, secondary electrons propagate with constant high kinetic energy of for example between 27 keV and 30 keV. Between beam tube segment 151.2 and 151.3, the electrostatic deflection scanner 222 is arranged. In this example, the second scanning deflector 222 is a two-stage electrostatic octupole scanner. Upstream of the electrostatic deflection scanner 222 in propagation direction of the secondary electron path 13, a first magnetic projection lens 205.1 is arranged. The detection unit 200 further comprises at least one static deflector or multi-pole corrector 220a, 220b, 220c for static adjustment of the secondary electron beam path 13. A pair of two further magnetic projection lenses 205.2 and 205.3 are configured to form the focus spots 15.i, 15.o of the secondary electron beamlets 9.i, 9.o in the secondary electron image plane 225 and to adjust an image rotation of the secondary electrons beamlets 9, induced by for example a change of an image surface 101 by objective lens 102. The three magnetic projection lenses 205.1, 205.2 and 205.3 and the at least one quasi-static multi-pole correctors 220 are connected to and controlled by the secondary beam-path control module 840. The elements are arranged and centered around the optical axis 2105 of the detection unit 200, which is for simplicity shown as a straight line; however, the optical axis 2105 can also comprise a curved segment for example within the beam divider 400.

Within the detection unit 200, at least a first cross-over 256 and a second cross-over 258 of the secondary electron beamlets 9 are formed. A cross-over is defined as the position along the secondary electron beam path 13, at which the plurality of secondary electron beamlets 9 intersect each other. Generally, a pupil plane or cross-over plane 256 or 258 is defined by the cross-over formed by the intersection of the secondary electron trajectories starting perpendicular to the image plane 101. An example is illustrated by trajectory 283 of secondary electron beamlet 9.o, which is starting at focus point 5.o perpendicular to the image plane 101, having two cross-overs 256 and 258 with the optical axis 203, which is perpendicular to the primary image plane 101. The positions of the two cross-over 256 and 258 define the positions of the pupil planes 21a and 21b of FIG. 1. In another example, a detection unit 200 comprises more than two cross-overs, for example a third cross-over.

In the example of FIG. 7, an aperture stop 284 is positioned within the second pupil plane 21b. The aperture stop 284 is typically of circular shape, but other shapes are possible as well. The aperture stop 284 has the function to serve during use as a contrast or pupil filter, with allows passage of identical angular intensity distributions or pupil distributions (see FIG. 4b) of each secondary electron beamlet 9 and is therefore responsible for an identical image contrast for each secondary electron beamlet 9. Some examples of aperture stops 284 are disclosed in PCT Application PCT/EP2023/025426, filed on Oct. 10, 2023, which is hereby incorporated by reference.

In presence of charging effects, however, the secondary electron beamlets can comprise an additional tilt component at the image plane 101, which corresponds to a displacement of at least parts of the intensity distribution in the pupil plane 21b. In such case, the aperture stop 284 centered at the optical axis 2105 filters out a decentered or asymmetrical part of the pupil distribution of the plurality of secondary electron beamlets. In an example, the detection unit 200 therefore further comprises a beam deflector 218 at an intermediate image plane position 211 within the secondary electron beam-path 13. Thereby, the plurality of secondary electron beamlets can be deflected without affecting the positions of the beam spots 15 of the secondary electron beamlets 9. In an example, the detection unit 200 therefore further comprises an adjustment or displacement mechanism 214 for positioning the aperture stop 284 at a decentered position within the pupil plane 21b. Thereby, a decentered part of the pupil distribution of the plurality of secondary electron beamlets can be filtered.

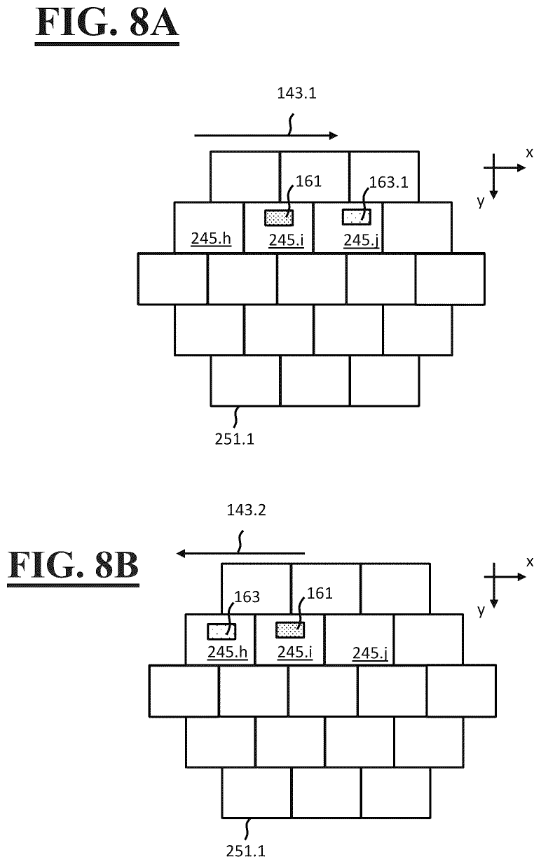

FIGS. 8a-b illustrate the effect of cross-talk due to a strong charging of pre-exposed surface areas 149. In this example, the additional displacement of the secondary electrons by extraction field 139 in presence of charging increases cross-talk, which means that a focus spot 15 on the detection plane 225 is increased such that secondary electrons generated by a first primary beamlet 3.i are collected by a detector element or group of detector elements assigned to a second primary beamlet 3.j. As a result, during imaging, an area 161 present on the wafer surface 25 in image patch 245.i of first beamlet 3.i contributes to the image formation of an adjacent image patch 245.j and generates there a ghost image 163. In FIG. 8a, a first example is illustrated with a first scanning direction 143.1 and a first ghost image 163.1 in the subsequent image patch 245.j, while in FIG. 8b, the scanning direction 143.2 is reversed and the ghost image 163.2 is formed within image of image patch 245.h.

The multi-beam system according to the first embodiment is configured for a first scanning image acquisition of a first image of a surface segment of a wafer and a subsequent second scanning image acquisition of a second image of the same surface segment of the wafer.

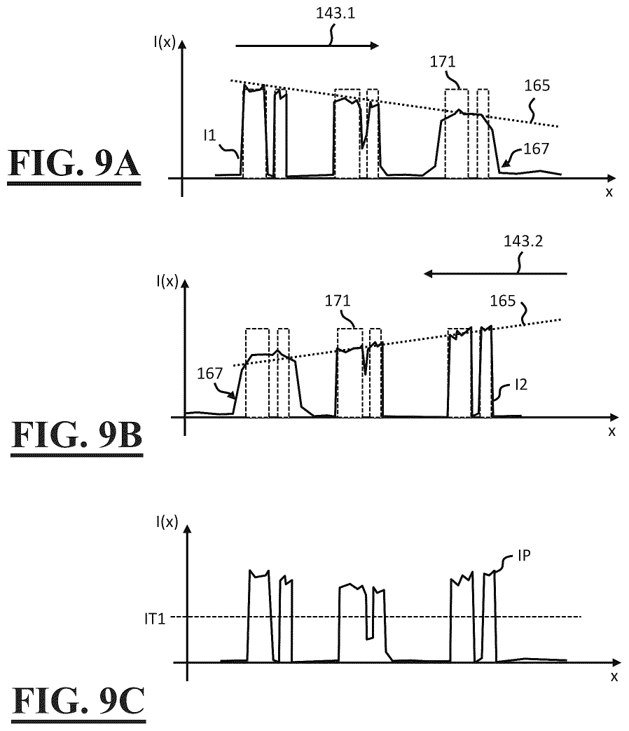

In a first example, the control unit 800 is configured to perform the first and the second scanning image acquisitions subsequently with different scanning directions. Thereby, as illustrated in FIGS. 8a-b, for example two different ghost images 163.1 and 163.2 are generated, and the ghost images 163.1 and 163.2 can be subtracted by image processing. A further example is illustrated in FIGS. 9a-c. FIG. 9a illustrates an image intensity acquired from a scanning line 241 in a first scanning direction 143.1 in positive x-direction. Along scanning line, different semiconductor structures 171 are present, which accumulate charge during exposure with primary electrons. During scanning acquisition, a charging effect of the pre-exposed surface area 149 is increasing, and a deflection effect of the pupil distribution 2107 and 2109 is increasing during scanning acquisition. Therefore, the secondary electrons passing a circular contrast filter 284 is decreasing during scanning and the signal I1 is decreasing in positive scanning direction. In this example, the charging effect increases linear, and the signal loss 165 is linear. In addition to the linear signal loss, the focus spots 15 are increased and a resolution is reduced. Therefore, a blur 167 due to charging increased with scanning direction 143.1. According to the first example, control unit 800 is configured to perform a second scanning image acquisitions subsequently with a different scanning direction. A result is illustrated in FIG. 9b, and intensity I2 is acquired. According to the first embodiment, the multi-beam charged particle beam system 1 comprises an image processing engine 890, which is configured to generate a processed image IP from the first image I1 and second image I2. A result is illustrated in FIG. 9c. Thereby, charging effects can be removed by image processing of two images with different charging effects. For example, each image I1 and I2 can be filtered by a local contrast filter, and the processed image IP can be obtained by the respective image parts of I1 or I2 with higher contrast. The processed image IP is then filtered for example by a threshold IT1 and edges of the semiconductor features 171 are detected with high resolution.

In a second example, the control unit 800 is configured to perform the first and the second scanning image acquisitions subsequently with different aperture filters (284a, 284b). Thereby, a charging property is pronounced and a charging effect, for example a charging effect to the low energy secondary electrons, is even more increased. Thereby, charging effects can be more easily detected and compensated for example by image processing.

In a third example, the control unit 800 is configured to perform the first and the second scanning image acquisitions subsequently with a different lateral position of the aperture filter (284) relative to the lateral position of the optical axis 2105. Thereby, a charging property is pronounced and a charging effect, for example a charging effect to the low energy secondary electrons, is even more increased. Thereby, charging effects can be more easily detected and compensated for example by image processing.

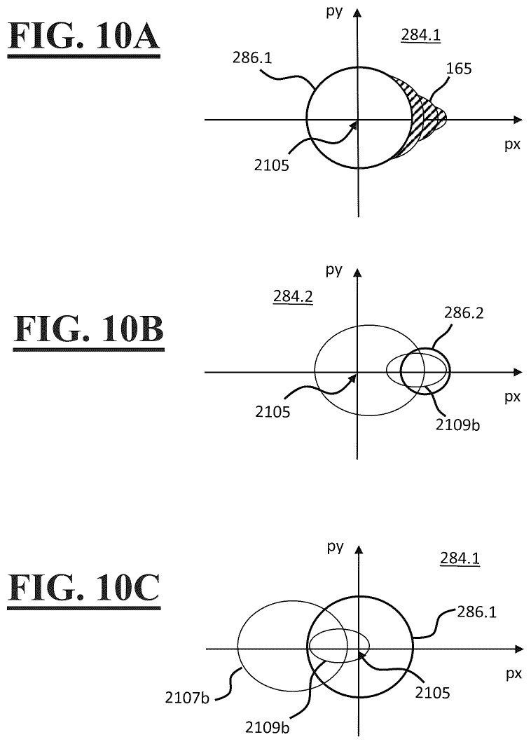

FIGS. 10a-c illustrate examples according to the second and third example. FIG. 10a shows a scanning image acquisition with a conventional aperture filter 284.1 with a large aperture opening 286.1 centered at the optical axis 2105 of the detection unit 200. Due to the increasing charging effect during image acquisition, a transmitted intensity I1 is decreasing due to the signal loss 165 according to charging effects. With increasing charging effect, the signal loss is also increasing (see example of FIGS. 9a-c). FIG. 10b illustrates a second image acquisition with a decentered second aperture stop 284.2 with a smaller aperture opening 286.2 decentered with respect to the optical axis. During scanning image acquisition, the intensity I2 of the low-energy secondary electrons 2109b which is passing the aperture filter opening 286.2 is increasing. From two images, a high-resolution image can be processed. FIG. 10c illustrates a further example of a signal collection of intensity I2 with the first aperture filter 284.1, but with a decentered pupil distribution 2107b, 2109b by action of the deflector 218 (see FIG. 7 and description of FIG. 7). By such a secondary electron beam deflection, more intensity of the pupil distribution 2109b of the low-energy secondary electrons is collected and an image of higher resolution is obtained. Furthermore, with the examples of FIGS. 10b and 10c, a sensitivity to charging effects is increased and charging effects can be detected more easily.

In a fourth example, the control unit 800 is configured to perform the first and the second scanning image acquisitions subsequently with a first kinetic energy and a second kinetic energy of the primary charged particle beamlets (3). Thereby, a charging property is reversed and a charging effect, for example two different ghost images 163.1 and 163.2, can be subtracted by image processing. An example is illustrated in FIGS. 11a-b, which uses same reference numbers as FIG. 4a and reference is also made to FIG. 4a. In FIG. 11a, the kinetic energy of primary electrons is selected below ELT2, and a negative charge is accumulated in pre-exposed surface area 149. In FIG. 11b, a kinetic energy of primary electrons is selected between ELT2 and EHT2, and a positive charge is collected in pre-exposed surface area 149, having the opposite effect to the electrical field vector 139.2 as in FIG. 11a. Thereby, different charging effects are collected in first and second intensity image I1 and I2 and resulting image IP can be processed with higher accuracy and resolution.

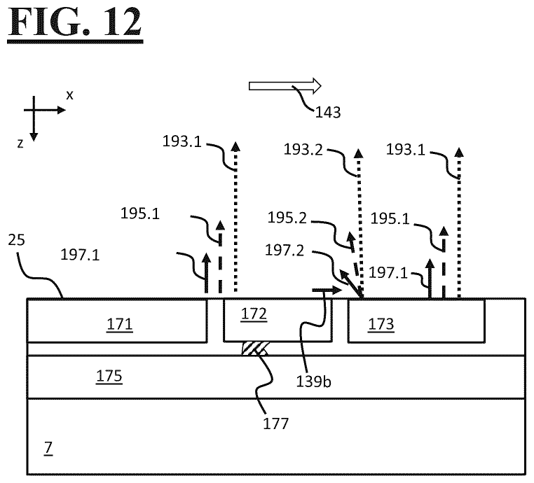

FIG. 12 illustrates an example of the method for the detection of a weak charging as an effect of a leakage defect 177. In this example, a semiconductor wafer 7 is structured by three isolated semiconductor structures 171, 172, 173, which can for example be metal structures such as contact pads embedded in isolators. Those structures form a capacity and accumulate charges during scanning. Structure 172 has a leakage defect to an underlying structure 175, such that charges can flow away to the underlying structure 175. During image scanning in scanning direction 143, no charge is build up in semiconductor structure 172. However, when the primary electron beam reaches semiconductor structure 173, a charge is generated and a field vector contribution 193b parallel to the scanning direction 143 is formed. In a similar example, metal structures 171, 172, 173 such as contact pads embedded in isolators are connected to an underlying conducting structure 175, such that all charges are drained to the underlying conducting structure 175. In case, however, if a structure 172 is insufficiently connected to underlying conducting structure 175, a weak charge is accumulated during scanning within the isolated structure 172 and a charge contrast of low energy secondary electrons can be extracted according to a method of the disclosure.

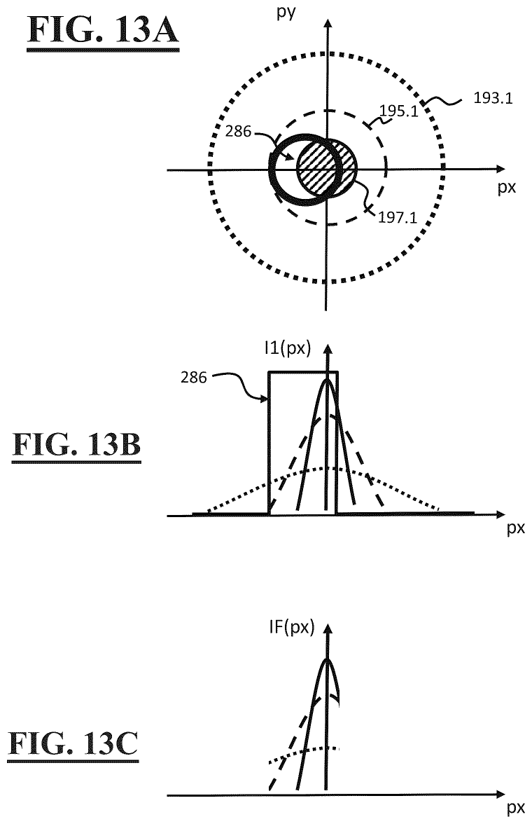

FIGS. 13a-c illustrate an example of the method of a contrast improvement for the imaging of weak charging objects, such as contact pads of low capacity illustrated in FIG. 12. FIGS. 13a-c illustrates the situation of no charging. A small, decentered aperture filter 286 is introduced in pupil plane 21b. The size of the aperture filter opening 286 is selected according to the angular spectrum of the low-energy secondary electrons. Low energy secondary electrons are more sensitive to weak charging effects. FIG. 13b illustrates the angular spectrum of three energy regimes similar to FIG. 5a and reference is made to FIG. 5a. In addition, the decentered filter function 286 is illustrated. FIG. 13c shows the filtered angular spectrum IF(px), which passes the aperture filter opening 286.

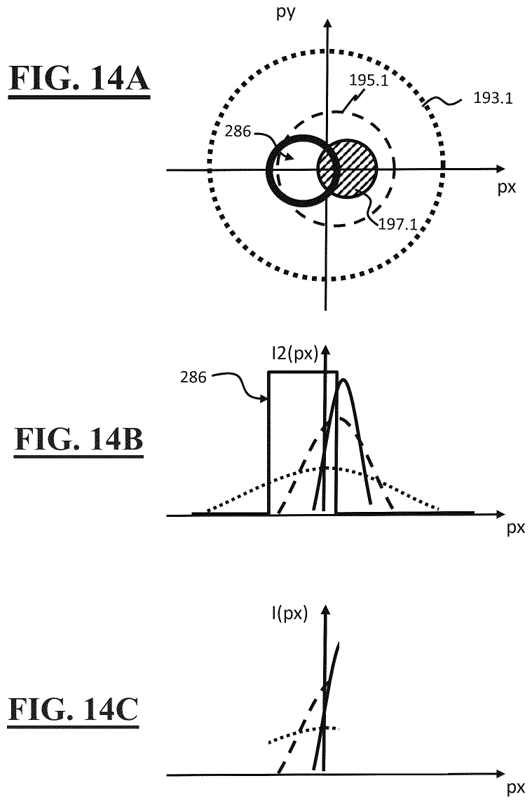

FIGS. 14a-c illustrate the angular distribution in presence of a weak charging object. Low energy secondary electrons are deflected and do not show a large overlapping area with the decentered aperture filter 286. FIG. 14b illustrates the angular spectrum of three energy regimes similar to FIG. 5b and reference is made to FIG. 5b. FIG. 14c shows the filtered angular spectrum. With the decentered filter 286, the integrated filtered Intensity IF in presence of a weak charging effect is drastically reduced and therefore, the weak charging effect becomes visible during imaging while it is not visible during conventional imaging with a large aperture stop.

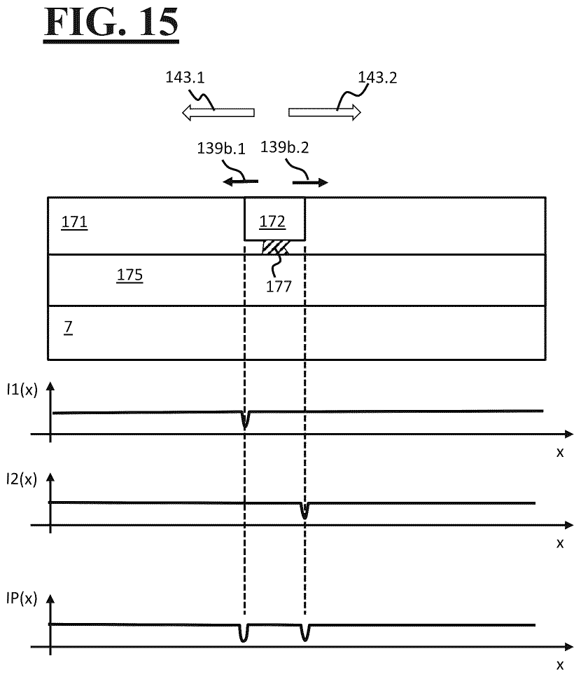

FIG. 15 illustrates another example of an imaging with increased contrast in presence of a weak charging object. According to this example, a first image is acquired with for example a decentered aperture stop 286 of FIG. 14a. During scanning in the first scanning direction 143.1 over a semiconductor object 172 with a leakage defect 177, charged build up and accumulate during scanning. A field gradient 139b.1 is generated in the first scanning direction at the first edge of the structure 172. According to this example, a second image is acquired with the same decentered aperture stop 286 of FIG. 14a. During scanning in the second scanning direction 143.2 over a semiconductor object 172 with a leakage defect 177, a field gradient 139b.2 is generated in the second scanning direction at the second edge of the structure 172. Each contrast-enhance image therefore shows one edge of the structure 172. Both images together can be processed to show the edges of feature 172. In an example, the charging effect is only visible at the second transition from the weak charging structure 172 to the embedding material 171. This is especially the case when weak charges are generated during scanning of each scanning image line 241 (see FIGS. 2a-c). As will be explained further down below, charges decay over time. Especially weak charges may decay between two consecutive scanning lines such that the first transition from embedding material 171 to the weak charging structure 172 in scanning direction does not show any charging effect.

Instead of changing the scanning direction from first to second scanning direction, it is however also possible to change the position of the displaced aperture filter opening 286 according to the scanning direction, or to decenter the pupil distribution of secondary electrons by static deflector 218. In each case, using a first image acquisition and a second image acquisition, a first and a second image are acquired, from which a processed image is generated. The first and the second image acquisition differ by at least one image acquisition setting selected from the group of image acquisition settings including a scanning direction, a change of an aperture filter position, a deflection angle imposed on the secondary electrons close to an intermediate field plane.

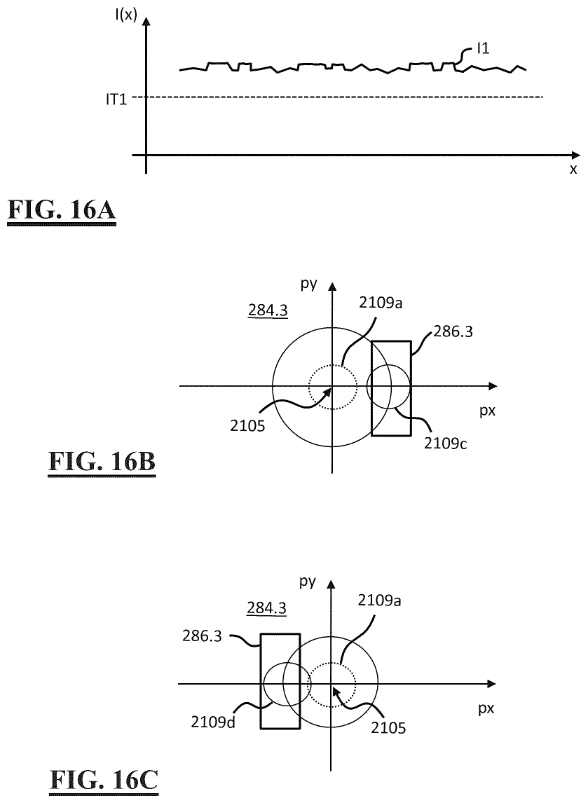

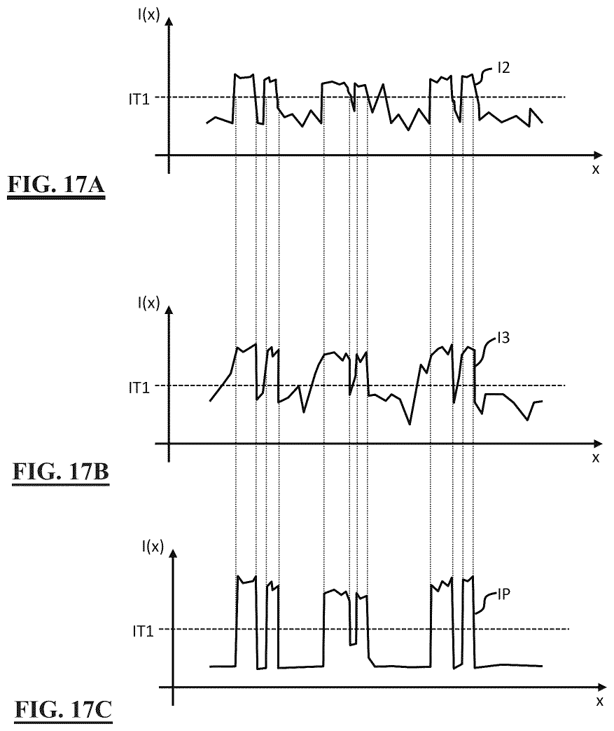

FIGS. 16a-c illustrate another example of weakly charging features within a wafer at a wafer surface. Some features are only weakly charged during image acquisition, for example with primary beamlets close to a transition energy ELT or EHT illustrated in FIG. 6. The weakly charged feature generates a weak field gradient, such that only secondary electrons of low energy are deflected by the weak field gradient. Therefore, in a conventional imaging with a conventional aperture stop 184.1 as illustrated in FIG. 9a, no significant contrast difference of weakly charged features of objects is visible. According to the example, a method of improved image contrast comprises placement of an aperture stop 284.3 with a smaller off-axis aperture opening 286.3 in the pupil plane 258 of the detection unit 200 (see FIG. 16b). Thereby, a sensitivity of the image acquisition with respect to the charging induced deflection of secondary electrons of low kinetic energy is increased, and an image contrast is improved. According to an example, a scanning direction of an image acquisition is changed and the position of the off-axis aperture opening 286.3 is adjusted according to the field gradient generated during image acquisition. This example is illustrated in FIG. 16c. FIG. 17a and FIG. 17b illustrate the corresponding image intensities of the first image acquisition in a first scanning direction and a first off-axis stop position as illustrated in FIG. 16b, and a second image acquisition in a second scanning direction and a second off-axis stop position as illustrated in FIG. 16c. From both images together, a high resolution and high-contrast image IP is computed by image processing, as illustrated in FIG. 17c.

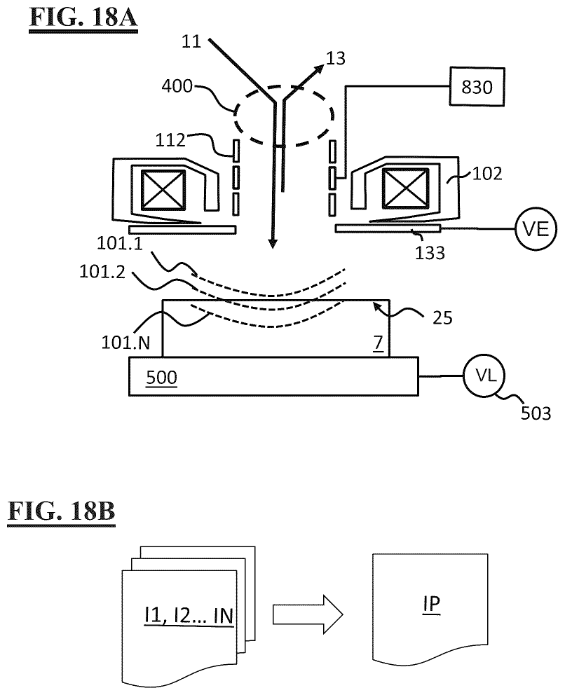

In a fifth example, the control unit 800 is configured to perform the first and the second scanning image acquisitions subsequently with different adjustment of the image surface (101). As explained in FIGS. 9a and 9b, charging also increases an image blur 167. On reason for an image blur 167 is a defocus of the primary electron beamlets 3, which lead to an axial displacement of the image surface 101.2. The axial displacement is for example more pronounced at a center of a surface segment 251 (see FIG. 2b), leading to a curved image surface 101 showing field curvature (FC). Such an example is illustrated in FIG. 18a. By acquiring at least two images of the surface segment with different axial distance of the image surface 101, for example with image surfaces 101.1, 101.2 and 101.3, at least two images are obtained in which different areas of a surface segment 251 are within focus range. Thereby, a high-resolution processed image IP can be processed by methods known as focus stacking. In difference to conventional focus stacking, the issue solved by the fifth example is not a surface topography, but a curvature of an image surface 101. The adjustment of the image surface 101.1 to 101.3 can be achieved by for example an additional electrostatic lens element 112 arranged in proximity to the deflection scanner 110, by objective lens 102, or by a stage 500 with an axial actuator (not shown).

Generally, the acquisition of images is not limited to two images, but the method is generally configured to combine several, for example up to N=3, N=5 or N=11 images with different intensity distributions I1 to IN due to signal loss, ghost images and resolution loss due to charging effects or curvature of the image surface 101. As illustrated in FIG. 18b, the image processing engine 890 is configured to process from the intensity distributions I1 to IN at least on processed image IP.

Generally, the multi-beam charged particle beam system 1 is configured for the acquisition of at least two subsequent images and is configured to combine several, for example up to N=3, N=5 or N=11 images with different intensity distributions I1 to IN acquired with different image acquisition properties as described in the examples above. Generally, the image processing engine 890 is configured to process from intensity distributions I1 to IN at least on processed image IP. Generally, the different image acquisition properties are selected from a group of image acquisition properties including selection and placement of aperture filter within the pupil plane of the detection unit, a scanning direction, a focus position or position of the image plane 101 by for example additional lens 112, a deflection angle imposed on the secondary electrons to generate an offset to the angular distribution of secondary electrons while keeping constant the position of the focus points 15 in an image plane 225 of the detection unit, a kinetic energy or landing energy of the primary electrons impinging on the surface 25 of the substrate 7, a position of the surface 25 with respect to the image plane 101 adjusted by the wafer stage 500.

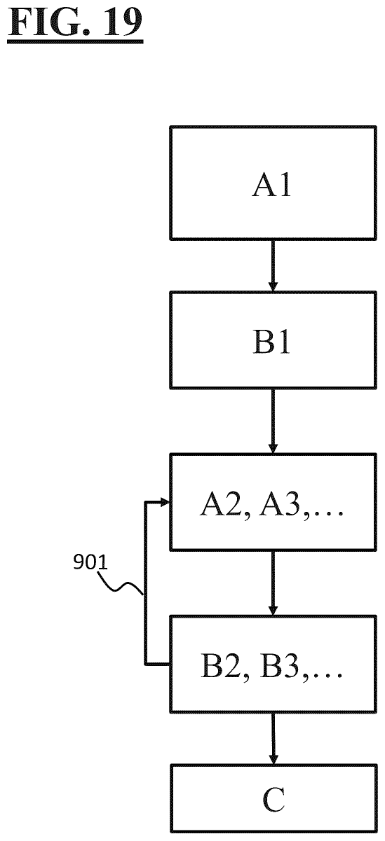

A method of image acquisition with increased accuracy and lower sensitivity to charging effects and field surface curvature is illustrated in FIG. 19. The method comprises a first step A1 of selecting a first image acquisition property S1. The method comprises a second step B1 of a first image acquisition I1. The method comprises a third step A2 of selecting a second image acquisition property S2, which is different to the first image acquisition property in at least one imaging property. The method comprises a fourth step B2 of a second image acquisition I2. After acquiring the second image I2 in step B2, the method can comprise at least one further steps A3 of selecting a third or further image acquisition property S3 . . . SN and at least one further steps B3 of a third or further image acquisition I3 . . . IN (indicated by iteration arrow 901).

Differences in image acquisition property can be differences in the scanning direction 143, differences in the selection of an aperture 284, differences in a position of an aperture filter opening 286 with respect to the optical axis 2105 of a detection unit, differences in a deflection angles introduced by deflector 218 close to an intermediate image plane 211 of the detection unit 200, differences in the kinetic energy or primary electrons, differences in an adjustment of an image surface 101 by either an adjustment of an objective lens 102 or a further electrostatic les 112, and differences in an placement of the surface 25 of a wafer 7 by a stage 500.

Differences in image acquisition property can further comprise a change in a scanning offset, for example after acquisition of the first image, a scanning offset is provided by the scanning operation control module for the scanning image acquisition of a second or further image. As a scanning offset for example a subpixel spacing is selected for the generation of super-resolution images. In another example, a larger scanning offset is selected to reduce or determine boundary charging effects during image acquisition.

After the acquisition of at least two images I1 and I2, the method comprises a final step C of determining a processed image IP using image processing methods. Image processing methods can include at least one member of the group of processing methods consisting of image processing operations to individual images, numerical operations on at least a pair of images, contrast-based image stitching, image correction, model-based image processing, and phase retrieval.

Operations to individual images include image processing operations such as noise filtering, image normalization, morphologic operations, thresholding or local contrast determination, were for example for each image area, a local contrast is computed by (Imax−Imin)/(Imax+Imin); other examples of local contrast determination is the computation of a derivation of an image in scanning direction, or the computation of the log slope of an image intensity, which is a very sensitive measure of contrast.

Numerical operations on at least a pair of images include image processing operations as for example addition, subtraction, multiplication, division, averaging, interpolation, convolution, correlation, or image interlacing of images acquired with a scanning offset to generate super-resolution images.

Contrast-based image stitching includes methods wherein the local contrasts of identical image areas of several images are compared, and a final image is stitched together with the image areas of maximum contrast. Some of these methods are known as “focus stacking”.

Image correction methods are including subtraction of filtered difference images (such as ghost images 163).

Model-based image processing includes methods wherein the acquired images I1 to IN are approximated by a feed-forward simulation according to an imaging model and the processed image IP is computed by inversion of the imaging model. An imaging model can include a charging property, an impact on the extraction field, an aperture filtering, a cross talk, a kinetic energy, and more. Such methods are sometimes also referred as super-resolution methods.

Phase retrieval is a special case of a model-based image processing method, where a phase distribution of each of the primary or secondary electrons is computed by methods known as phase retrieval from at least two intensity images. Generally, due to the incoherent secondary electron generation in electron optical imaging, more than two intensity images I1 and I2 are used for phase retrieval.

Generally, the acquisition and processing of images is not limited to two images, but the method is generally configured to combine several, for example up to N=3, N=5 or N=11 images with different intensity distributions I1 to IN due to signal loss, ghost images and resolution loss due to charging effects or curvature of the image surface 101. As illustrated in FIG. 18b, the image processing engine 890 is configured to process from the intensity distributions I1 to IN at least on processed image IP.

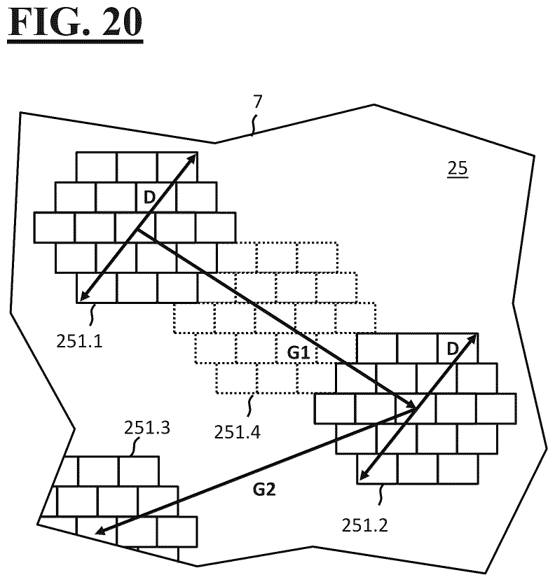

FIG. 20 illustrates a further example. As described above, during image acquisition, a charging of a pre-exposed surface area 149, and, after completion of an image acquisition of an image of surface segment 251.1, consequently a charging of a complete surface segment 251.1 is accumulated. Accumulated charges typically decay with decay times given by thermal diffusion within semiconductors and residual conductivity of semiconductors. Decay times can be in the order of below milliseconds to few seconds. Therefore, in an example it is desirable to continue a second image acquisition of the same surface segment 251.1 only after a period exceeding a decay time. An example of the method of improved image acquisition as illustrated in FIG. 19 therefore comprises
a first step A1 of selecting a first surface segment 251.1
a second step B1 of a first image acquisition I1 of the first surface segment 251.1.
a third step A2 of selecting a second surface segment 251.2, which is different to the first surface segment 251.1 and has a distance of G1 to the first surface segment.
a fourth step B2 of a second image acquisition I2 of the second surface segment 251.2.
a fifth step C of image processing and image stitching (similar to the image processing step of the second embodiment.

After acquiring the second image I2 in step B2, the method can comprise at least one further steps A3 of selecting a third or further surface segment 251.3 to 251.N and at least one further steps B3 of a third or further image acquisition I3 . . . IN.

With proper selection of the distance G1 (and G2), thereby forming gaps between subsequently imaged surface segments 251.1 to 251.N, an impact of charging of pre-exposed surface areas 149 are minimized. With placing, for example, a fourth surface segment 251.4 next to a first surface segment 251.1 after a long delay exceeding a decay time of charges, an impact of charging effects is minimized. An image acquisition can involve an image acquisition time of more than 1 second, for example about 3 s, which is typically in the order of or exceeding a decay time of charges.

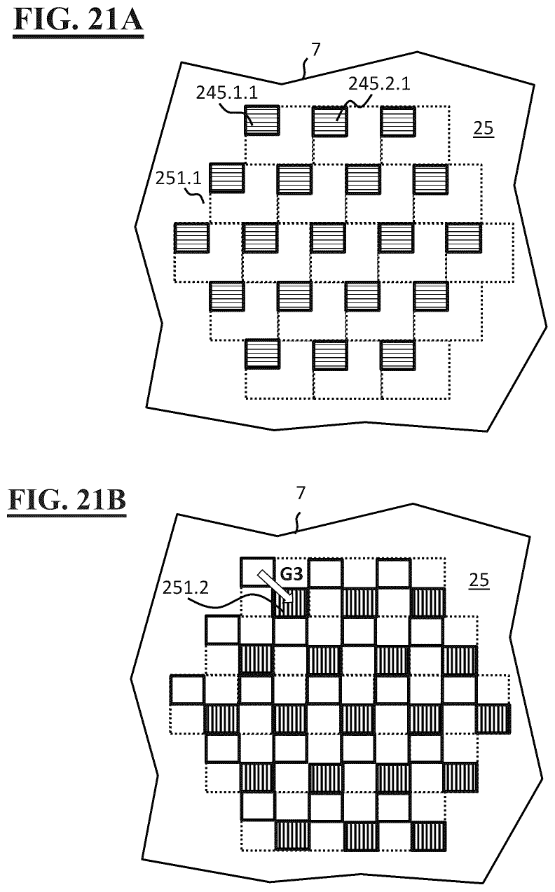

FIGS. 21a-b illustrate a further example. In the example, the scanning image acquisition of the image subfields are selected to acquire smaller image patches 245.1 for each primary beamlet, such that two neighboring image patches or subfields 245.1.1 and 245.2.1 form a gap in between. After acquisition of the first non-connected surface segment 251.1, the position of the wafer 7 relative to the plurality of image subfield 245.i.1 is changed by displacement vector G3 and an image of a second first non-connected surface segment 251.2 is acquired. The displacement can be achieved by either a placement of the wafer 7 by stage 500 or be generating an offset to the deflection scanner 110. After acquisition of four non-connected, interlaced surface segments 251.1 to 251.4, a complete image of a surface segment 251 is stitched together in image processing step C.

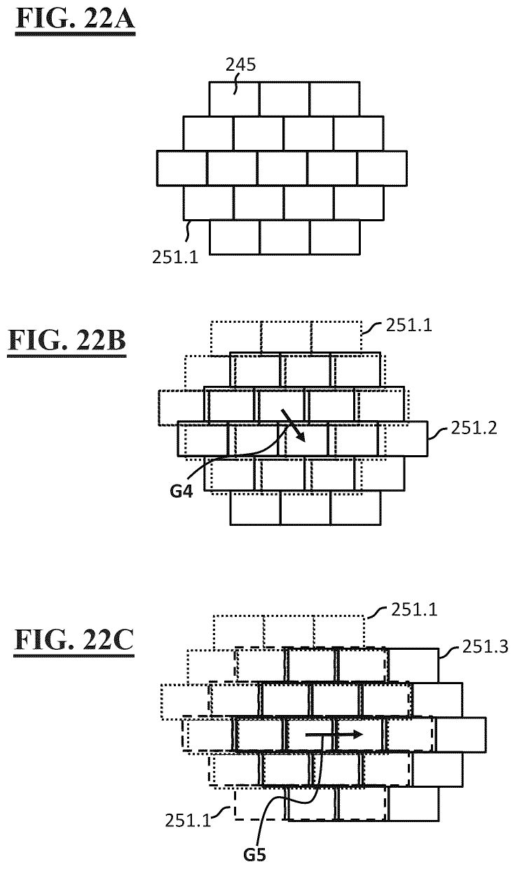

FIGS. 22a-c illustrate a further example. Here, the scanning image acquisition of the second image of a surface segment 251.2 is displaced with respect to the first image of a surface segment 251.1 by a distance G4 which is approximately given by a diameter of an image patch 245. Thereby, a beam to beam variation can be determined from at least two images and a beam-to-beam variation of the image acquisition can be determined and subtracted from the images by image processing.

The disclosure is further described by following clauses:
Clause 1: A multi-beam charged particle system (1) with an object irradiation unit (100) configured for irradiating a surface (25) of a wafer (7) with a plurality of focus spots (5) of a plurality of primary charged particle beamlets (3), forming there during use a plurality of interaction volumes (141), comprising
   a mechanism for forming and adjusting an image surface (101), in which the plurality of focus spots (5) are formed,
   a scanning operation control module (860) for operating a collective multi-beam raster scanner (110) for scanning during use the plurality of focus spots (5) within the image surface (101), and
   a mechanism (133, 503) for adjusting a kinetic energy of the plurality of primary charged particle beamlets (3),
   a detection unit (200), comprising a plurality of charged particle lens elements (205) and at least one aperture filter (284), configured for imaging a plurality of secondary charged particle beamlets (9), which are excited during use at the plurality of interaction volumes (141), on an image sensor (600),
   a control unit (800), configured for a first scanning image acquisition of a first image of a surface segment of a wafer and a subsequent second scanning image acquisition of a second image of the surface segment of the wafer, wherein at least one of the following conditions are complied with:
   a) the first and the second scanning image acquisitions are subsequently performed with different scanning directions,
   b) the first and the second scanning image acquisitions are subsequently performed with different adjustment of the image plane (101),
   c) the first and the second scanning image acquisitions are subsequently performed with primary charged particle beamlets (3) of different kinetic energy,
   d) the first and the second scanning image acquisitions are subsequently performed with different aperture filters (284a, 284b),
   e) the first and the second scanning image acquisition are subsequently performed with a displacement of the lateral position of the aperture filter (284) relative to the lateral position of the plurality of secondary electron beamlets (9) in a pupil plane (21b) of the detection unit (200).
Clause 2: The system (1) of clause 1, wherein the control unit (800) further comprises an image processing engine (890) configured to compute at least a processed image IP from the first and second image.
Clause 3: The system (1) of clause 1 or 2, wherein the mechanism for adjusting the kinetic energy of the plurality of primary charged particle beamlets (3) are comprising a voltage supply unit (503) configured for supplying during use a voltage to the wafer (7) and for generating a decelerating or extraction field (505).
Clause 4: The system (1) of any of the clauses 1 to 3, wherein the mechanism for adjusting the image surface (101) are comprising at least one of an objective lens (102) and an electrostatic lens (112) of the object irradiation unit (100).
Clause 5: The system (1) of any of the clauses 1 to 4, wherein the detection unit (200) further comprises an aperture filter module (214) configured to adjust the lateral position of the aperture filter (284).
Clause 6: The system (1) of any of the clauses 1 to 5, wherein the detection unit (200) further comprises a deflector (218) configured to adjust a lateral position of a pupil distribution of the plurality of secondary electron beamlets (9) in a pupil plane (21b) of the detection unit (200).
Clause 7: The system (1) of any of the clauses 1 to 6, where the detection unit (200) further comprises an aperture filter module (214) configured to exchange a first aperture filter (284a) with a second aperture filter (284b).
Clause 8: A method of operating a multi-beam charged particle system (1), comprising
   selecting a first image acquisition property,
   acquiring a first image of a surface segment of a wafer with a plurality of primary charged particle beamlets (3),
   changing the first image acquisition property into a second image acquisition property,
   acquiring a second image of the surface segment of the wafer with the plurality of primary charged particle beamlets (3),
   image processing the first and the second images to obtain at least one processed image IP.
Clause 9: The method of clause 8, wherein the selecting of the first image acquisition properties comprises at least one of a group of image acquisition properties including
   a selection of a scanning direction (143) of the plurality of primary charged particle beamlets (3),
   a selection of a scanning offset of the plurality of primary charged particle beamlets (3),
   a selection of an image surface (101) position, in which a plurality of focus points (5) of the plurality of primary charged particle beamlets (3) are formed,
   a selection of a kinetic energy or landing energy of the plurality of the primary charged particle beamlets (3),
   a selection of a first aperture filter (284a) of a detection unit (200),
   a selection of a lateral position of a plurality of secondary electron beamlets (9) in a pupil plane (21b) and the first aperture filter (284).
Clause 10: The method of clause 9, wherein the changing of the first image acquisition properties comprises at least one of a group of changes including
   a change of the scanning direction (143),
   a change of a scanning offset,
   a change of the position of the image surface (101),
   a change of the kinetic energy or landing energy of the plurality of primary charged particle beamlets (3),
   a change of the aperture filter (284a) into a second aperture filter (284b),
   a change of a lateral position of a plurality of secondary electron beamlets (9) or the aperture filter (284) in the pupil plane (21b).
Clause 11: The method of any of the clauses 8 to 10, wherein the image processing comprises at least one computation of a group including the computation of a difference image, an average image, superimposed image, an interlaced image, a fused image, or a noise-reduced image.
Clause 12: The method of any of the clauses 8 to 11, wherein the changing of the first image acquisition properties comprises a change of the scanning direction, or a change of the lateral position of a plurality of secondary electron beamlets (9) relative to the aperture filter (284), and wherein the image processing comprises the computation of a difference image.
Clause 12: The method of any of the clauses 8 to 12, further comprising
   changing the first and the second image acquisition property into at least a further image acquisition property,
   acquiring at least a further image of the surface segment of the wafer (7) with the plurality of primary charged particle beamlets (3),
   image processing the first, the second and the further images to obtain at least one processed image.
Clause 12: The method of clause 13, wherein the changing comprises a change of the position of the image surface (101) and wherein the image processing comprises an image fusion from image regions of the first, the second and further images with maximum local contrast.
Clause 13: The method of clause 13, wherein the changing comprises a change of the position of the image surface (101) and wherein the image processing comprises the computation of a model based super-resolution image.
Clause 14: The method of clause 13, wherein the changing comprises a change of the position of the image surface (101) and wherein the image processing comprises a phase retrieval.
Clause 15: A multi-beam charged particle system (1) comprising
   an object irradiation unit (100),
   a detection unit (200), and
   a control unit (800) with a memory (880) for storing a set of instructions and a processor (840) configured to execute the set of instructions to cause the multi-beam charged particle system (1) to perform a methods of any of the clauses 8 to 14.
Clause 16: A multi-beam charged particle system (1) with an object irradiation unit (100) configured for irradiating a surface (25) of a wafer (7) with a plurality of focus spots (5) of a plurality of primary charged particle beamlets (3), forming there during use a plurality of interaction volumes (141), comprising
   a scanning operation control module (860) for operating a collective multi-beam raster scanner (110) for deflecting during use the plurality of focus spots (5),
   a detection unit (200) comprising a plurality of charged particle lens elements (205), configured for imaging a plurality of secondary charged particle beamlets (9), which are excited during use at the plurality of interaction volumes (141), on an image sensor (600),
   a control unit (800), configured for a first scanning image acquisition of a first image of a first surface segment of width D of a wafer and a subsequent second scanning image acquisition of a second image of a second surface segment of width D of the wafer, wherein the first surface segment and the second surface segment are arranged at a distance G, with G>=2×D.
Clause 17: A method of operating a multi-beam charged particle system (1), comprising
   acquiring a first image of a first surface segment of width D of a wafer (7) with a plurality of primary charged particle beamlets (3),
   moving the wafer (7) by a first distance G with of G>1.5×D,
   acquiring a second image of a second surface segment of width D of the wafer (7) with the plurality of primary charged particle beamlets (3).
Clause 18: The method of clause 19, further comprising
   moving the wafer (7) by a second distance G with of G>=D,
   acquiring a further image of a further surface segment of width D of the wafer (7) with the plurality of primary charged particle beamlets (3),
   stitching an image of a surface segment of width 3×D of the wafer (7).
Clause 19: A method of operating a multi-beam charged particle system (1), comprising
   acquiring a first image I1 of a first surface segment of a wafer (7) with a plurality of primary charged particle beamlets (3), wherein the first image comprises distinct image patches of size AP for each of the plurality of primary charged particle beamlets (3),
   moving the wafer (7) by a first distance G with of G<=AP,
   acquiring at least a second image I2 of width D of the wafer (7) with the plurality of primary charged particle beamlets (3).
Clause 20: The method according to clause 19, further comprising a step of image processing of the first and at least second image I1, I2 to form a processed image IP.
Clause 21: A method of operating a multi-beam charged particle system (1), comprising
   acquiring a first image I1 of a first surface segment of a wafer (7) with a plurality of primary charged particle beamlets (3) by scanning image acquisition with a pixel resolution,
   applying an offset signal to the scanning deflector 110 to cause a scanning offset in at least a first direction given by a fraction of the pixel resolution,
   acquiring at least a second image I2 the wafer (7) with the plurality of primary charged particle beamlets (3),
   process by image processing a super-resolution image IP from the first and second image I1 and I2.
Clause 22: A method of operating a multi-beam charged particle system (1), comprising
   acquiring a first image I1 of a first surface segment of a wafer (7) with a plurality of primary charged particle beamlets (3) by scanning image acquisition in a first scanning direction 143.1 with a first position of an aperture stop 268.3 arranged in a pupil plane 258 of a detection unit (200) of the multi-beam charged particle system (1),
   changing the first scanning direction 143.1 into a second scanning direction 143.2, different to the first scanning direction 143.1,
   changing the first position of the aperture stop 268.3 into a second position of the aperture stop 268.3 arranged in a pupil plane 258 of a detection unit (200),
   acquiring at least a second image I2 the wafer (7) with the plurality of primary charged particle beamlets (3),
   processing by image processing a processed image IP from the first image I1 and the at least second image I2.
Clause 23. A multi-beam charged particle beam system (1) comprising:
   a memory for storing a set of instructions,
   a processor configured to execute the set of instructions to cause the multi-beam charged particle beam system (1) to perform any of the methods of clauses 17 to 22.
Clause 24. A method of imaging weak charging objects with large contrast, comprising
   acquiring a first image I1 with a first aperture filter for filtering low energy secondary electrons in a first scanning direction to detect a first edge of a weakly charging structure,
   acquiring a second image I2 with a second aperture filter for filtering low energy secondary electrons in a second scanning direction to detect a second edge of the weakly charging structure,
   combining first image I1 and second image I2 to a processed image IP comprising first and second edges of the weakly charging structure.

The disclosure is however not limited to the embodiments or clauses described above.

The embodiments or examples can be fully or partly combined with one another, and variations and modifications are possible as well.

A list of reference numbers is provided:
1 multi-beamlet charged-particle system
3 primary charged particle beamlets, or plurality of primary charged particle beamlets
5 primary charged particle beam spot
7 object
9 secondary electron beamlet, forming the plurality of secondary electron beamlets
11 secondary electron beam path
13 primary beam path
15 secondary charged particle image spot
21 common pupil plane
25 surface of object
61 SE yield curve of first material composition
62 SE yield curve of second material composition
63 low energy transition point
65 high energy transition point
100 object irradiation unit
101 image surface
102 objective lens
103 field lens
108 first beam cross over
110 scanning deflector
112 electrostatic lens
133 electrode
137 equipotential lines of extraction field
139 electrical field vector and vector components
141 interaction volume
143 Scanning direction
149 pre-exposed surface area
151 beam tube segment
161 charging wafer surface area
163 ghost image
165 signal loss
167 resolution loss
171 semiconductor structure
172 semiconductor structure
173 semiconductor structure
175 guiding structure
177 leakage defect
191 ideal secondary electron trajectory
193 high-energy secondary electron beamlet
195 mid-range energy secondary electron beamlet
197 low-energy secondary electron beamlet
200 detection unit
205 lens element
211 intermediate image plane
214 aperture filter module
215 movement mechanism
218 deflector
220 alignment deflectors
222 second deflection system
225 detection plane
241 scanning line
243 fly-back
245 image patch of single beamlet
251 image of surface segment
256 first beam cross over
258 pupil plane or second beam cross over
281 aperture ray
282 aperture ray with charging
283 chief ray
284 aperture filter
286 aperture opening
300 charged-particle multi-beamlet generator
301 charged particle source
303 collimating lenses
304 filter plate
305 primary multi-beamlet-forming unit
306 multi-aperture plates
307 terminating multi-aperture plate
308 field lenses
309 primary electron beam
321 intermediate image surface
400 beam splitter unit
500 sample stage
503 Sample voltage supply
505 wafer chuck
600 image sensor
707 Interaction volume
711 layers of a wafer
728 conducting elements if first layer
729 conducting elements if second layer
731 conducting elements if third layer
800 control unit
810 imaging control module
820 secondary beam-path control module
830 primary beam-path control module
840 Control operation processor
850 stage control module
860 scanning operation control module
870 contrast control module
880 memory
890 image processing engine
901 iteration
2105 optical axis of detection unit
2107 pupil distribution of high energy secondary electrons
2109 pupil distribution of low energy secondary electrons

What is claimed is:

1. A multi-beam charged particle system, comprising:
an irradiation unit configured to irradiate an image surface with a plurality of focus spots of a plurality of primary charged particle beamlets to form a plurality of interaction volumes;
a mechanism configured to form and adjust the image surface;
a scanning operation control module configured to operate a collective multi-beam raster scanner to scan the plurality of focus spots within the image surface;
a mechanism configured to adjust a kinetic energy of the plurality of primary charged particle beamlets;
a detection unit comprising a plurality of charged particle lens elements and an aperture filter, the detection unit configured to image a plurality of secondary charged particle beamlets onto an image sensor, the plurality of secondary charged particle beamlets being formed at the plurality of interaction volumes;
a control unit to control a first scanning image acquisition of a first image of a surface segment of an object in the image surface and a subsequent second scanning image acquisition of a second image of the surface segment of the object so that at least one of the following holds:
a) the first and the second scanning image acquisitions are performed with different scanning directions;
b) the first and the second scanning image acquisitions are performed with different adjustment of the image surface;
c) the first and the second scanning image acquisitions are performed with primary charged particle beamlets of different kinetic energy;
d) the first and the second scanning image acquisitions are performed with different aperture filters; and
e) the first and the second scanning image acquisition are performed with a different lateral position of the aperture filter relative to a lateral position of the plurality of secondary charged particle beamlets.

2. The system of claim 1, wherein the control unit further comprises an image processing engine configured to compute at least a processed image from the first and second images.

3. The system of claim 1, wherein the mechanism configured to adjust the kinetic energy of the plurality of primary charged particle beamlets comprises a voltage supply unit configured to supply a voltage to the object and to generate a decelerating field or an extraction field.

4. The system of claim 1, wherein the mechanism configured to adjust the image surface comprises at least one of an objective lens (102) and an electrostatic lens (112) of the object irradiation unit (100).

5. The system of claim 1, wherein the detection unit further comprises an aperture filter module configured to adjust the lateral position of the aperture filter.

6. The system of claim 1, wherein the detection unit further comprises a deflector configured to adjust the lateral position of the plurality of secondary charged particle beamlets with respect to the lateral position of the aperture filter.

7. The system of claim 1, wherein the detection unit further comprises an aperture filter module configured to exchange the aperture with a different aperture filter.

8. The system of claim 1, wherein at least two of a) through e) hold.

9. A method of operating a multi-beam charged particle system, the method comprising:
selecting a first image acquisition property;
acquiring a first image of a surface segment of an object with a plurality of primary charged particle beamlets generated by the multi-beam charged particle system;
changing the first image acquisition property to a second image acquisition property;
acquiring a second image of the surface segment of the object with the plurality of primary charged particle beamlets generated by the multi-beam charged particle system; and
image processing the first and the second images to obtain a processed image.

10. The method of claim 9, wherein the selecting of the first image acquisition properties comprises selecting at least one member selected from the group consisting of:
a scanning direction of the plurality of primary charged particle beamlets;
an image surface position in which a plurality of focus points of the plurality of primary charged particle beamlets are formed;
a kinetic energy of the plurality of primary charged particle beamlets;
an aperture filter of a detection unit of the multi-beam charged particle system;
a lateral position of a plurality of secondary charged particle beamlets in a pupil plane, the plurality of secondary charged particle beamlets being generated by an interaction of the plurality of primary secondary charged particle beamlets with the object;
a lateral position of an aperture filter of a detection unit of the multi-beam charged particle system.

11. The method of claim 10, wherein changing the first image acquisition property comprises changing at least one member selected from the group consisting of the scanning direction, the position of the image surface, the kinetic energy of the plurality of primary charged particle beamlets, the aperture filter with the different aperture filter, and the lateral position of the plurality of secondary charged particle beamlets, and the lateral position of the aperture filter in the pupil plane.

12. The method of claim 9, wherein image processing comprises computing at least one member selected from the group consisting of a difference image, an average image, a superimposed image, a fused image, and a noise-reduced image.

13. The method of claim 9, wherein changing the first image acquisition property comprises a change of the scanning direction, or a change of the lateral position of the plurality of secondary charged particle beamlets relative to the aperture filter, and wherein image processing comprises computing a difference image.

14. The method of claim 9, further comprising:
changing the first and the second image acquisition properties into a third image acquisition property;
acquiring a third image of the surface segment of the object with the plurality of primary charged particle beamlets; and
image processing the first, the second and third images to obtain a processed image.

15. The method of claim 14, wherein changing the first and the second image acquisition properties into a third image acquisition property comprises changing the position of the image surface, and wherein image processing comprises an image fusion from image regions of the first, the second and third images with maximum local contrast.

16. The method of claim 14, wherein changing the first and the second image acquisition properties into a third image acquisition property comprises changing the position of the image surface, and wherein image processing comprises computing a model based super-resolution image.

17. The method of claim 14, wherein changing the first and the second image acquisition properties into a third image acquisition property comprises changing the position of the image surface, and wherein image processing comprises a phase retrieval.

18. One or more machine-readable hardware storage devices comprising instructions that are executable by one or more processing devices to perform operations comprising the method of claim 10.

19. A system, comprising:
one or more processing devices; and
one or more machine-readable hardware storage devices comprising instructions that are executable by one or more processing devices to perform operations comprising the method of claim 10.

20. The system of claim 19, further comprising:
an object irradiation unit; and
a detection unit.
